(19) United States
(12) Patent Application Publication
(10) Pub. No.: US 2022/0348712 A1
(43) Pub. Date: Nov. 3, 2022

(54) POLYTHIOPHENES IN ORGANIC SOLVENTS

(71) Applicant: Heraeus Deutschland GmbH & Co. KG, Hanau (DE)

(72) Inventors: Rüdiger SAUER-STIEGLITZ, Hanau (DE); Wilfried LOVENICH, Hanau (DE); Armin SAUTTER, Hanau (DE); Philipp VIEHMANN, Hanau (DE)

(21) Appl. No.: 17/764,751

(22) PCT Filed: Sep. 29, 2020
(86) PCT No.: PCT/EP2020/077250

§ 371 Date: Mar. 29, 2022

(30) Foreign Application Priority Data
Sep. 30, 2019 (EP) 19200608.8
Dec. 20, 2019 (EP) 19219007.2

(51) Int. Cl. C08G 61/12; G03F 7/038; H01B 1/12; G03F 7/16

(52) U.S. Cl. CPC C08G 61/126; G03F 7/0382; H01B 1/127; G03F 7/168; G03F 7/162; C08G 2261/1424; C08G 2261/3223; C08G 2261/43

(57) ABSTRACT

The present invention relates to a composition comprising
i) at least one polythiophene comprising monomer units of structure (Ia) or (Ib)

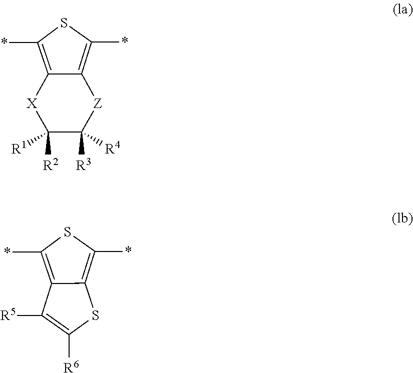

in which *, X, Z, R, and R¹-R⁶ are as defined herein;
ii) at least one organic compound carrying one or two inorganic acid group(s), preferably one or two sulfonic acid group(s), one or two sulfuric acid group(s), one or two phosphonic acid group(s) or one or two phosphoric acid group(s), or a salt of said organic compound, wherein the molecular weight of the organic compound or the salt thereof is less than 1,000 g/mol; and
iii) at least one organic solvent. A method of preparing such compounds is also provided.

The present invention relates to a composition comprising at least one polythiophene. The present invention also relates to a process for preparing a composition, to a composition obtainable by this process, to a layer structure, to a process for the preparation of a layer structure, to a layer structure obtainable by this process, to an electronic component and to the use of composition according to the present invention.

Polythiophenes are widely used as intrinsically conductive polymers. In particular poly(3,4-ethylenedioxythiophene) (PEDOT) has found many industrial applications such as solid electrolyte capacitors, antistatic coatings, electroluminescent lamps, organic light emitting diodes, organic solar cells and many others. For a large number or these applications PEDOT is used as a polymer complex with polystyrene-sulfonic acid as counter-ion dispersed in water or mixtures of water and other solvents (also referred to as “PEDOT/PSS”).

Efforts have been made to supply PEDOT in aprotic solvents in order to extend the range of applications. WO-A-2012/059215 A1 discloses the use of block-copolymers as counter-ions rendering the dispersion soluble in organic, aprotic solvents. The solubility parameters of the block-copolymer dominate and limit the solubility properties of the resulting PEDOT complex. Hence the dispersion becomes unstable once solvents such as PGMEA or ethanol are added.

KR-A-100945056 describes the polymerization of 3,4-ethylenedioxythiophene in water in the presence of surfactants. Subsequently the solvent is removed and is replaced by organic solvents. Such a re-dispersing process, however, is expensive and undesirable.

McCullough et al. (“A Simple Method to Prepare Head-to-Tail Coupled, Regioregular Poly(3-alkylthiophenes) Using Grignard Metathesis”; Adv. Mater. 1999, 11, 250) describe the synthesis of regioregular copolymers that can be dispersed in a number of solvents. However, the coupling through metal-organic compounds is expensive and the resulting polymers show only limited conductivity. Hence their application is limited to hole-transport layers, where only conductivity through the layer is required.

The object of the present invention was to overcome the disadvantages of the prior art relating to electrically conductive polymers that are based on thiophene-monomers, preferably on 3,4-ethylenedioxythiophene-monomers.

Particularly, it was an object of the present invention to provide a composition comprising polythiophenes that is based on organic solvents, preferably on organic aprotic solvents, and that can be dispersed in a wide range of solvents. The composition should also be characterized in that conductive layers prepared with such a composition should be highly conductive and highly transparent. Furthermore, the composition should be able to achieve low sheet resistance when blended with inert polymers such as polyacrylates. Furthermore, the composition should be characterized in that they can easily be diluted with organic solvents.

It was also an object of the present invention to provide a process that allows the preparation of such advantageous compositions in as few process steps as possible.

A contribution to at least partly solving at least one, preferably more than one, of the above objects is made by the independent claims. The dependent claims provide preferred embodiments which contribute to at least partly solving at least one of the objects.

A contribution to solving at least one of the objects according to the invention is made by an embodiment 1 of a composition 1 comprising
i) at least one polythiophene, preferably at least one cationic polythiophene, comprising monomer units of structure (Ia) or (Ib)

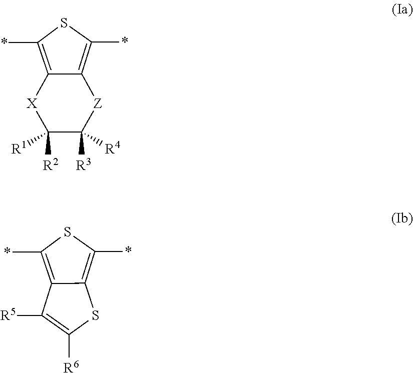

in which
   indicates the bond to the neighboring monomer units,
   X,Z represent O or S,
   R¹-R⁶ independently from each other represent a hydrogen atom or an organic residue R,
with the proviso that at least one of residues R¹ to R⁴ and one of residues R⁵ and R⁶ represents an organic residue R;
ii) at least one organic compound carrying one or two inorganic acid group(s), preferably one or two sulfonic acid group(s), one or two sulfuric acid group(s), one or two phosphonic acid group(s) or one or two phosphoric acid group(s), or a salt of said organic compound, wherein the molecular weight of the organic compound or the salt thereof is less than 1,000 g/mol, preferably less than 900 g/mol, more preferably less than 800 g/mol, even more preferably less than 700 g/mol, even more preferably less than 600 g/mol and even more preferably less than 500 g/mol;
iii) at least one organic solvent.

Surprisingly it was found that polythiophenes comprising monomer units of structure (Ia) or (Ib) as described above, for example copolymers of 3,4-ethylenedioxythiophene and derivatives of 3,4-ethylenedioxythiophene in which at least one of the hydrogen atoms of the ethylene group is substituted by an organic residue R, which use organic compounds carrying one or two inorganic acid group(s), such as a sulfonic acid group (—SO₂OH), a sulfuric acid group (—O—SO₂OH), a phosphonic acid group (—PO(OH)₂), a phosphoric acid group (—O—PO(OH)₂), or a salt of at least one of these groups and having a molecular weight of less than 1,000 g/mol, preferably monovalent sulfonic acid anions, as counter-ions can be dispersed in wide range of solvents. If organic residue R corresponds to an alkyl group, particularly to a linear or branched alkyl group having formula —CₙH₂ₙ₊₁ in which n is an integer in the range from 1 to 20, preferably to a branched alkyl group in which n is an integer in the range from 3 to 15 and more preferably in the range from 3 to 10, or if organic residue R corresponds to a branched ether group, complexes of such polythiophenes and the above described organic compounds carrying one or two inorganic acid groups(s) are particularly advantageous as into compositions, preferably dispersions, in which these complexes are dispersed in protic or aprotic solvents, large amounts of non-conductive binders, particular poly(meth)acrylates, (meth)acrylic resins, and polysilicones, can be added without unduly reducing the conductivity of these compositions.

In an embodiment 2 of composition 1 according to the invention, composition 1 is designed according to its embodiment 1, wherein the composition is present in the form of a dispersion or solution (and wherein the organic solvent iii), preferably the aprotic solvent iii), thus serves as the dispersant or solvent), wherein the polythiophene i) and the organic compound ii) (which is preferably present in the form of an anion), preferably the copolymer i) and the organic compound ii), form a complex that is dispersed or dissolved, preferably homogeneously dispersed or solved, in the organic solvent iii). Most preferably, the compositions according to the present invention are dispersions in which the complex of the polythiophene i) and the organic compound ii) is homogeneously dispersed in the organic solvent iii). However, in the compositions according to the present invention the transitions between a “dispersion” and a “solution” can be fluid depending on the actual nature of the polythiophene i), the organic compound ii) and the organic solvent iii).

In an embodiment 3 of composition 1 according to the invention, composition 1 is designed according to its embodiment 2, wherein the polythiophene/organic compound complex i)/ii) is dispersed at a weight content of 30% or less, preferably 20% or less and more preferably 10% or less, in each case based on the total weight of the dispersion.

In an embodiment 4 of composition 1 according to the invention, composition 1 is designed according to anyone of its embodiments 1 to 3, wherein the organic residue R does not carry anionic groups. Preferably, residue R does not carry any sulfonic acid groups or salts of this group.

In an embodiment 5 of composition 1 according to the invention, composition 1 is designed according to anyone of its embodiments 1 to 4, wherein the organic residue R is selected from the group consisting of an alkyl group, an alkoxy group, an aryl group, an ether group and an ester group.

In an embodiment 6 of composition 1 according to the invention, composition 1 is designed according to anyone of its embodiments 1 to 5, wherein the polythiophene is a homopolymer or copolymer comprising monomer units of structure (Ia) or structure (Ib) in which X and Z represent O, preferably monomer units of structure (Ia) in which X and Z represent O, and wherein three of the residues selected from the group consisting of R¹, R², R³ and R⁴ and one of the residues selected from the group consisting of R⁵ and R⁶ represent a hydrogen atom and the remaining residue represents an ether group having the structural formula (IIa)

—(CR⁷R⁸)ₙ—O—R⁹ (IIa)

wherein
R⁷ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁷ is H;
R⁸ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁸ is H;
n is an integer in the range from 0 to 10, preferably in the range from 1 to 6 and more preferably in the range from 1 to 3, wherein it is most preferred that n is 1; and
R⁹ is an alkyl group, an alkoxy group, an aryl group, an ether group or an ester group, preferably a C₁-C₃₀ alkyl group, more preferably a C₂-C₂₅-alkyl group, even more preferably a C₅-C₂₀-alkyl group.

In an embodiment 7 of composition 1 according to the invention, composition 1 is designed according to anyone of its embodiments 1 to 5, wherein the polythiophene is a homopolymer or copolymer comprising monomer units of structure (Ia) or structure (Ib) in which X and Z represent O, preferably monomer units of structure (Ia) in which X and Z represent O, and wherein at least two of the residues selected from the group consisting of R¹, R², R³ and R⁴ and one of the residues selected from the group consisting of R⁵ and R⁶, preferably three of the residues selected from the group consisting of R¹, R², R³ and R⁴ and one of the residues selected from the group consisting of R⁵ and R⁶ represent a hydrogen atom and the remaining residues, preferably the remaining residue represent/s an alkyl group having formula (IIb)

—CₙH₂ₙ₊₁ (IIb)

wherein n is an integer in the range from 1 to 20, preferably in the range from 2 to 15, more preferably in the range from 3 to 15 and even more preferably in the range from 3 to 10. A particularly preferred alkyl group is an ethyl group, a n-propyl group, a n-butyl group, a n-pentyl group, a n-hexyl group, a n-heptyl group, a n-octyl group, a n-nonyl group or a n-decyl group, wherein an ethyl group, a n-butyl group and a n-decyl group are particularly preferred and wherein a n-butyl group is most preferred.

Suitable examples of monomer units of structure (Ia) carrying a branched alkyl group or more than one alkyl group comprise a compound selected from the group consisting of compounds (A), (B), (C) and (D):

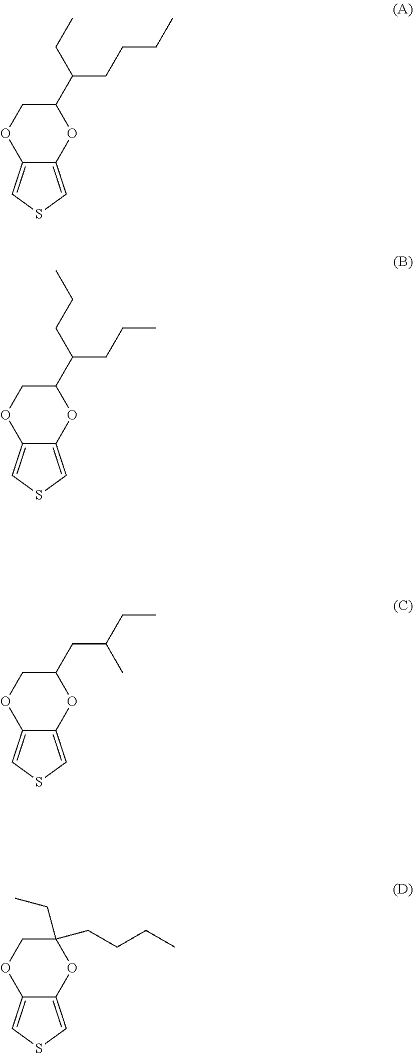

In an embodiment 8 of composition 1 according to the invention, composition 1 is designed according to anyone of its embodiments 1 to 5, wherein the polythiophene is a homopolymer or copolymer comprising monomer units of structure (Ia) or structure (Ib) in which X and Z represent O, preferably monomer units of structure (Ia) in which X and Z represent O, and wherein three of the residues selected from the group consisting of R¹, R², R³ and R⁴ and one of the residues selected from the group consisting of R⁵ and R⁶ represent a hydrogen atom and the remaining residue represents a branched alkyl group or a branched ether group, preferably a branched ether group, wherein a “branched ether group” in the sense of the present invention is preferably an ether group in which at least one of the two organic residues that are bonded to the oxygen atom are branched organic residues, i. e. organic residues comprising at least one carbon atom that is bonded via a single bond to at least three carbon atoms or to at least two carbon atoms and to the oxygen atom that is part of the ether group. More preferably, the remaining residue represents a branched ether group having the structural formula (IIc)

—(CR¹⁰R¹¹)ₙ—O—R¹² (IIc)

wherein
R¹⁰ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹⁰ is H;
R¹¹ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹¹ is H;
n is an integer in the range from 0 to 10, preferably in the range from 1 to 6 and more preferably in the range from 1 to 3, wherein it is most preferred that n is 1; and
R¹² is a branched organic residue, preferably a branched alkyl group or a branched arylalkyl group, more preferably a branched alkyl group or a branched arylalkyl group that do not carry an unsaturated C═C-bond in the alkyl chain, even more preferably an organic residue having formula (IId)

—(CHR¹³)ₘ—R¹⁴ (IId)
wherein
   m is 1, 2 or 3,
   R¹³ is H or a C₁-C₁₂ alkyl group, preferably a C₂-C₁₀ alkyl group and more preferably a C₃-C₈ alkyl group, even more preferably a butyl group, with the provisio that in only one of the m structural units —CHR¹³— residue R¹³ is a C₁-C₁₂ alkyl group;
   R¹⁴ is a C₁-C₁₀-alkyl group, preferably a C₂-C₆-alkyl group, or a aryl group.

In an embodiment 9 of composition 1 according to the invention, composition 1 is designed according to its embodiment 8, wherein the polythiophene is a homopolymer or copolymer comprising monomer units selected from the group consisting of compounds (E), (F) and (G):

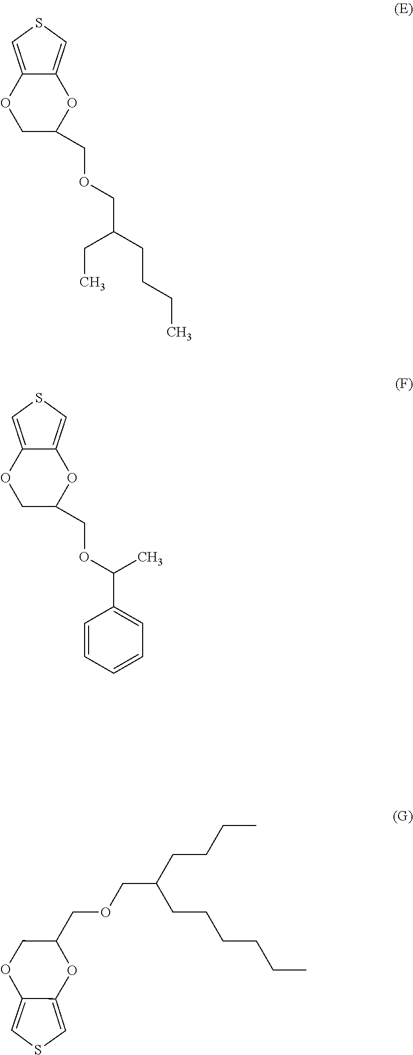

In connection with embodiment 8 and 9 of composition 1 according to the present invention it may also be possible to use organic compounds as component ii) that carry more than two inorganic acid groups and the molecular weight of which is larger than 1,000 g/mol, such as polystyrene sulfonic acid (PSS).

In an embodiment 10 of composition 1 according to the invention, composition 1 is designed according to anyone if its embodiments 1 to 9, wherein the at least one polythiophene i) is a copolymer of 3,4-ethylenedioxythiophene and at least one derivative of 3,4-ethylenedioxythiophene having the structural formula (Ia) in which X and Z represent O, wherein the at least one organic solvent iii) preferably is an aprotic solvent iii). In this case, the polythiophene i) is thus copolymer of 3,4-ethylenedioxythiophene and at least one derivative of 3,4-ethylenedioxythiophene in which at least one of the hydrogen atoms of the ethylene group is substituted by an organic residue R.

In an embodiment 11 of composition 1 according to the invention, composition 1 is designed according to its embodiment 10, wherein the derivative of 3,4-ethylenedioxythiophene has the structural formula (Ia′):

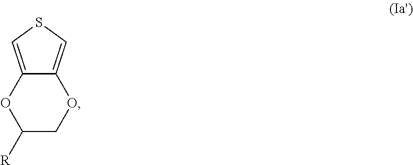

in which R is preferably selected from the group consisting of an alkyl group, an alkoxy group, an aryl group, an ether group and an ester group.

In an embodiment 12 of composition 1 according to the invention, composition 1 is designed according to its embodiment 11, wherein the organic residue R is an ether group.

In an embodiment 13 of composition 1 according to the invention, composition 1 is designed according to its embodiment 12, wherein the ether group has the structural formula (IIa)

—(CR⁷R⁸)ₙ—O—R⁹ (IIa)

wherein
R⁷ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁷ is H;
R⁸ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁸ is H;
n is an integer in the range from 0 to 10, preferably in the range from 1 to 6 and more preferably in the range from 1 to 3, wherein it is most preferred that n is 1; and
R⁹ is an alkyl group, an alkoxy group, an aryl group, an ether group or an ester group, preferably a C₁-C₃₀ alkyl group, more preferably a C₂-C₂₅-alkyl group, even more preferably a C₅-C₂₀-alkyl group.

In an embodiment 14 of composition 1 according to the invention, composition 1 is designed according to its embodiment 13, wherein the derivative of 3,4-ethylenedioxythiophene has the general formula (III)

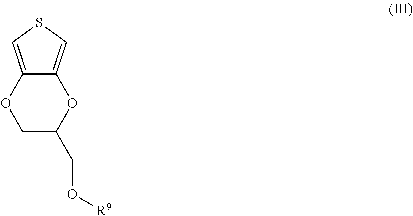

in which R⁹ is an alkyl group, an alkoxy group, an aryl group, an ether group or an ester group, preferably a C₁-C₃₀ alkyl group, more preferably a C₂-C₂₅-alkyl group, even more preferably a C₅-C₂₀-alkyl group.

In an embodiment 15 of composition 1 according to the invention, composition 1 is designed according to its embodiment 14, wherein the derivative of 3,4-ethylenedioxythiophene has the general formula (IV)

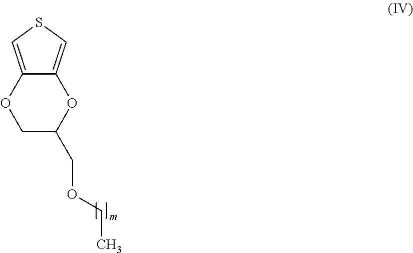

wherein m is an integer in the range from 0 to 24, preferably in the range from 1 to 19 and more preferably in the range from 4 to 14, wherein it is most preferred that m is 9.

In an embodiment 16 of composition 1 according to the invention, composition 1 is designed according to its embodiment 11, wherein the organic residue R is an alkyl group.

In an embodiment 17 of composition 1 according to the invention, composition 1 is designed according to its embodiment 16, wherein the alkyl group has formula (IIb)

—CₙH₂ₙ₊₁ (IIb)

wherein n is an integer in the range from 1 to 20, preferably in the range from 2 to 15, more preferably in the range from 3 to 15 and even more preferably in the range from 3 to 10. A particularly preferred alkyl group is an ethyl group, a n-propyl group, a n-butyl group, a n-pentyl group, a n-hexyl group, a n-heptyl group, a n-octyl group, a n-nonyl group or a n-decyl group, wherein an ethyl group, a n-butyl group and a n-decyl group are particularly preferred and wherein a n-butyl group is most preferred.

In an embodiment 18 of composition 1 according to the invention, composition 1 is designed according to its embodiment 17, wherein the derivative of 3,4-ethylenedioxythiophene has the general formula (V)

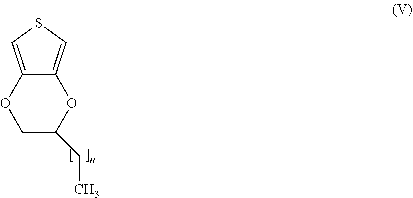

wherein n is in the range from 0 to 19, preferably in the range from 1 to 14 and more preferably in the range from 2 to 9. It is particularly preferred that n is 2, 3 or 4, wherein n=3 is most preferred.

In an embodiment 19 of composition 1 according to the invention, composition 1 is designed according to its embodiment 11, wherein the organic residue R is a branched alkyl group or a branched ether group, preferably a branched ether group, more preferably a branched ether group having the structural formula (IIc)

−(CR¹⁰R¹¹)ₙ—O—R¹² (IIc)

wherein
R¹⁰ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹⁰ is H;
R¹¹ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹¹ is H;
n is an integer in the range from 0 to 10, preferably in the range from 1 to 6 and more preferably in the range from 1 to 3, wherein it is most preferred that n is 1; and
R¹² is a branched organic residue, preferably a branched alkyl group or a branched arylalkyl group, more preferably a branched alkyl group or a branched arylalkyl group that do not carry an unsaturated C═C-bond in the alkyl chain, even more preferably an organic residue having formula (IId)

—(CHR¹³)ₘ—R¹⁴ (IId)
wherein
   m is 1, 2 or 3,
   R¹³ is H or a C₁-C₁₂ alkyl group, preferably a C₂-C₁₀ alkyl group and more preferably a C₃-C₈ alkyl group, even more preferably a butyl group, with the provisio that in only one of the m structural units —CHR¹³— residue R¹³ is a C₁-C₁₂ alkyl group;
   R¹⁴ is a C₁-C₁₀-alkyl group, preferably a C₂-C₆-alkyl group, or a aryl group.

In an embodiment 20 of composition 1 according to the invention, composition 1 is designed according to its embodiment 19, wherein the polythiophene is a homopolymer or copolymer comprising monomer units selected from the group consisting of compounds (E), (F) and (G):

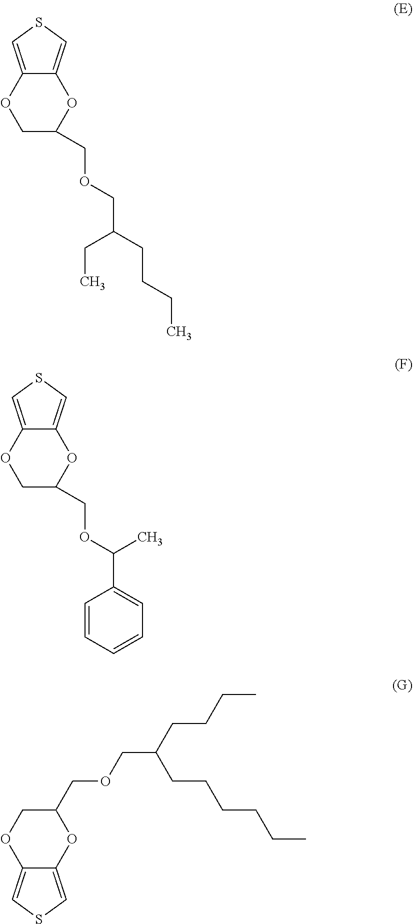

In an embodiment 21 of composition 1 according to the invention, composition 1 is designed according to anyone of its embodiments 1 to 20, wherein the copolymer i) comprises 5 to 95% monomer units, preferably 10 to 80% monomer units and more preferably 20 to 60% monomer units that are based on the derivative of 3,4-ethylenedioxythiophene, in each case based on the total number of monomer units (i.e. based on the total number of 3,4-ethylenedioxythiophene-monomer units and monomer units based on the derivative of 3,4-ethylenedioxythiophene).

In an embodiment 22 of composition 1 according to the invention, composition 1 is designed according to anyone of its embodiments 1 to 21, wherein the copolymer i) comprises at least 30 wt.-%, preferably at least 40 wt.-% and more preferably at least 70 wt.-% monomer units that are based on the derivative of 3,4-ethylenedioxythiophene, in each case based on the total number of monomer units (i.e. based on the total weight of 3,4-ethylenedioxythiophene-monomer units and monomer units based on the derivative of 3,4-ethylenedioxythiophene).

In an embodiment 23 of composition 1 according to the invention, composition 1 is designed according its embodiment 8, wherein the at least one polythiophene i) is a copolymer of
α) at least one derivative of 3,4-ethylenedioxythiophene having the structural formula structural formula (Ia′)

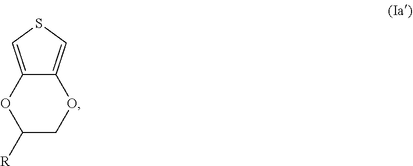

in which R is a branched alkyl group or a branched ether group, preferably a branched ether group, more preferably a branched ether group having the structural formula (IIc) as defined above,
β) at least one derivative of 3,4-ethylenedioxythiophene having the structural formula structural formula (Ia′)

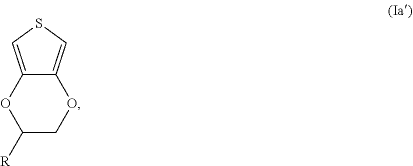

in which R is an alkyl group having the structural formula (IIb) as defined above, wherein a thiophene derivative selected from the group consisting of 2-ethyl-2,3-dihydrothieno[3,4-b]-1,4-dioxine, 2-propyl-2,3-dihydrothieno-[3,4-b]-1,4-dioxine 2-butyl-2,3-dihydrothieno[3,4-b]-1,4-dioxine, 2-decyl-2,3-dihydrothieno[3,4-b][1,4]dioxine is preferred and wherein 2-butyl-2,3-dihydrothieno[3,4-b]-1,4-dioxine (Butyl-EDOT) is particularly preferred,
   and optionally
γ) 3,4-ethylenedioxythiophene.

In an embodiment 24 of composition 1 according to the invention, composition 1 is designed according to its embodiment 23, wherein the copolymer i) comprises 5 to 99 mol.-%, preferably 15 to 70 mol-% and more preferably 30 to 50 mol-% monomer units that are based on monomers α), 5 to 95 mol-%, preferably 30 to 90 mol-% and more preferably 50 to 70 mol-% monomer units that are based on monomers β) and 0 to 50 mol-%, preferably 0 to 35 mol-% and more preferably 0 to 20 mol-% monomer units that are based on monomers γ), in each case based on the total amount of monomers α), β) and γ) in the copolymer, wherein the amounts of monomers α), β) and γ) sum up to 100 mol-%. According to a particularly preferred copolymer i) the copolymer does not comprise 3,4-ethylenedioxythiophene as a comonomer.

In an embodiment 25 of composition 1 according to the invention, composition 1 is designed according to anyone of its embodiments 1 to 24, wherein the inorganic acid group is a sulfonic acid group (—SO₂OH), a sulfuric acid group (—O—SO₂OH), a phosphonic acid group (—PO(OH)₂) or a phosphoric acid group (—O—PO(OH)₂), preferably a sulfonic acid group (—SO₂OH).

In an embodiment 26 of composition 1 according to the invention, composition 1 is designed according to anyone of its embodiments 1 to 25, wherein the organic compound ii) is an anionic surfactant.

In an embodiment 27 of composition 1 according to the invention, composition 1 is designed according to its embodiment 26, wherein the anionic surfactant is a sulfonic acid (R—SO₂OH), an ester of sulfuric acid (R—O—SO₂OH) or a salt of one of these esters, preferably a sulfonic acid. In this context it is particularly preferred that the anionic surfactant is a monovalent or divalent sulfonic acid (i.e. a compound that carries only a single sulfonic acid group or two sulfonic acid groups), most preferably a monovalent sulfonic acid.

In an embodiment 28 of composition 1 according to the invention, composition 1 is designed according to its embodiment 27, wherein the anionic surfactant is dodecylbenzene sulfonic acid or a salt thereof. The term “dodecyl sulfonic acid” as used herein also encompassed mixtures of alkylbenzene sulfonic acids which, in addition to dodecylbenzene sulfonic acid, further comprises alkylbenzene sulfonic acids with alkyl chains that are longer or shorter than the dodecyl-group.

In an embodiment 29 of composition 1 according to the invention, composition 1 is designed according to anyone of its embodiments 1 to 28, wherein the weight ratio of polythiophene i) to organic compound ii) or the salt thereof, preferably the weight ratio of copolymer i) to organic compound ii) or the salt thereof, is in the range from 1:30 to 1:0.1, preferably in the range from 1:20 to 1:0.2 and more preferably in the range from 1:5 to 1:0.5.

In an embodiment 30 of composition 1 according to the invention, composition 1 is designed according to anyone of its embodiments 1 to 29, wherein the at least one organic solvent iii), preferably the at least one aprotic solvent iii), has a boiling point (determined at a pressure of 1013 mbar) in the range from 50 to 300° C., preferably in the range from 60 to 250° C. and more preferably in the range from 70 to 220° C.

In an embodiment 31 of composition 1 according to the invention, composition 1 is designed according to anyone of its embodiments 1 to 30, wherein the at least one organic solvent is an aprotic solvent iii), more preferably is a polar aprotic solvent.

In an embodiment 32 of composition 1 according to the invention, composition 1 is designed according to its embodiment 31, wherein the dielectric constant of the polar aprotic solvent iii) is less than 20, preferably less than 10 and more preferably less than 7.

In an embodiment 33 of composition 1 according to the invention, composition 1 is designed according to its embodiment 31 or 32, wherein the polar aprotic solvent iii) has a dipole moment of less than 4 D, preferably less than2 D and more preferably less than 1.5 D.

In an embodiment 34 of composition 1 according to the invention, composition 1 is designed according to anyone of its embodiments 1 to 33, wherein the at least one organic solvent iii) is selected from the group consisting of aromatic hydrocarbons, esters, ethers, alcohols and mixtures thereof.

In an embodiment 35 of composition 1 according to the invention, composition 1 is designed according to its embodiment 34, wherein the at least one organic solvent iii) is selected from the group consisting of toluene, xylene, anisole, methyl benzoate, ethyl benzoate, propyl benzoate, butyl benzoate, methyl acetate, ethyl acetate, propyl acetate, butyl acetate, octyl acetate, methyl propionate, ethyl propionate, propyl propionate, butyl propionate, 1-methoxy-2-propylacetat, 1-methoxy-2-propanol, butanol, 2-propanol, ethanol and mixtures thereof or mixtures of one or two of these aprotic solvents with one or two further solvents. In case of a mixture of two or more organic solvents, it is particularly preferred that at least one of these solvents is an aprotic solvent iii).

In an embodiment 36 of composition 1 according to the invention, composition 1 is designed according to anyone of its embodiments 1 to 35, wherein the composition comprises
i) 0.01 to 20 wt.-%, preferably 0.02 to 10 wt.-% and more preferably 0.1 to 5 wt.-%, of the polymer;
ii) 0.01 to 15 wt.-%, preferably 0.02 to 10 wt.-% and more preferably 0.1 to 5 wt.-%, of the organic compound;
iii) 50 to 99.98 wt.-%, preferably 70 to 99.86 wt.-% and more preferably 85 to 99.3 wt.-%, of the solvent or solvent mixtures, preferably of the aprotic solvent or solvent mixtures;
iv) 0 to 15 wt.-%, preferably 0.1 to 10 wt.-% and more preferably 0.5 to 5 wt.-%, of an additive being different from components i) to iii),
   wherein the total weight of components i) to iv) sums up to 100 wt.-%.

In an embodiment 37 of composition 1 according to the invention, composition 1 is designed according to anyone of its embodiments 1 to 36, wherein the composition comprises, as a further component iv) being different from components i) to iii), a non-conductive oligomer or polymer, preferably a non-conductive oligomeric or polymeric binder. A “non-conductive oligomeric or polymeric binder” in the sense of the present invention is preferably a layer of an oligomer or a polymer a layer which has an electrical conductivity of less than 10⁻⁶ S/cm, preferably less than 10⁻⁸ S/cm and most preferably less than 10⁻¹⁰ S/cm. In contrast, “a conductive polymer” (the polythiophene i) or the polythiophene-copolymer i) in the composition according to the present invention in the sense of the present invention is preferably a polymer a layer of which has an electrical conductivity of at least 10⁻⁶ S/cm, preferably at least 10⁻⁵ S/cm and most preferably 10⁻⁴ S/cm.

In an embodiment 38 of composition 1 according to the invention, composition 1 is designed according to its embodiment 37, wherein the non-conductive polymeric binder is selected from the group consisting of a polyolefin, a polyvinyl acetate, a polycarbonate, a poly(meth)acrylate, a polyvinyl butyral, a poly(meth)acrylic acid amide, a polystyrene, a polyacrylonitrile, a polyvinyl chloride, a polyvinyl pyrrolidone, a polybutadiene, a polyisoprene, a polyether, a polyester, a polyurethane, a polyamide, a polyimide, a polysulphone, a polysilicone, an epoxy resin, a styrene-acrylate, a vinyl acetate/acrylate or an ethylene/vinyl acetate copolymer, a polyvinyl alcohol, a cellulose derivative or a mixture comprising at least two of these polymers, wherein a poly(meth)acrylate and a polysilicone are particularly preferred non-conductive polymeric binders. Also suitable as non-conductive polymeric binders are multifunctional (meth)acrylates such as dipentaerythritol penta-/hexaacrylate.

In an embodiment 39 of composition 1 according to the invention, composition 1 is designed according to its embodiment 38, wherein the poly(meth)acrylate is selected from the group consisting of poly(methyl acrylate), poly(methyl methacrylate), poly(ethyl acrylate), poly(ethyl methacrylate), poly(n-propyl acrylate), poly(n-propyl methacrylate), poly(isopropyl acrylate), poly(isopropyl methacrylate), poly(n-butyl acrylate), poly(n-butyl methacrylate), poly(isobutyl acrylate), poly(isobutyl methacrylate), poly(tert.-butyl acrylate), poly(tert.-butyl methacrylate), poly(2-ethylhexyl acrylate), poly(2-ethylhexyl methacrylate), poly(cyclohexyl acrylate), poly(cyclohexyl methacrylate), poly(phenyl acrylate), poly(phenyl methacrylate), poly(benzyl acrylate), poly(benzyl methacrylate) and copolymers of these polyacrylates or polymethacrylates.

In an embodiment 40 of composition 1 according to the invention, composition 1 is designed according to anyone of its embodiments 37 to 39, wherein the composition comprises the non-conductive polymeric binder iv), preferably the poly(meth)acrylate and/or the polysilicone, and the polythiophene/organic compound complex i)/ii) in a mass ratio of at least 20:1, preferably at least 25:1 and more preferably at least 30:1.

In an embodiment 41 of composition 1 according to the invention, composition 1 is designed according to anyone of its embodiments 37 to 40, wherein a conductive layer prepared with the composition has a sheet resistance of at most 1×10¹⁰ Ohm/sq, preferably at most 5×10⁹ Ohm/sq and more preferably of at most 1×10⁸ Ohm/sq.

In an embodiment 42 of composition 1 according to the invention, composition 1 is designed according to anyone of its embodiments 1 to 41, wherein the composition comprises less than 2 wt.-%, preferably less than 1 wt.-% and most preferably less than 0.1 wt.-% water, in each case based on the total weight of the composition.

In an embodiment 43 of composition 1 according to the invention, composition 1 is designed according to anyone of its embodiments 1 to 42, wherein the composition has a total metal content of less than 30 ppm, preferably less than 15 ppm and more preferably less than 5 ppm, in each case based on the total weight of the composition. Metals particularly include sodium, potassium and iron. Most preferably, the composition has an iron content of less than 30 ppm, preferably less than 15 ppm and more preferably less than 5 ppm, in each case based on the total weight of the composition

In an embodiment 44 of composition 1 according to the invention, composition 1 is designed according to anyone of its embodiments 1 to 43, wherein a conductive layer prepared with the composition has a conductivity of more than 1 S/cm, preferably more than 2 S/cm and most preferably more than 5 S/cm.

A contribution to solving at least one of the objects according to the invention is also made by an embodiment 1 of a process 1 for preparing a composition, preferably a dispersion, the process comprising the steps of
I) providing a reaction mixture comprising
   i) thiophene monomer units of structure (VIa) or (VIb)

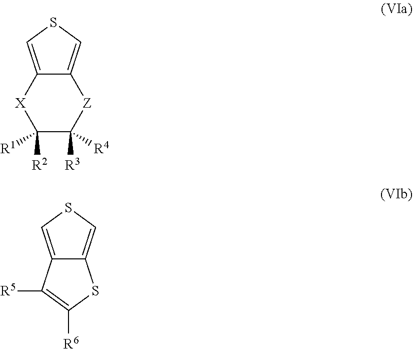

in which
   X,Z represents O or S,
   R¹-R⁶ independently from each other represent a hydrogen atom or an organic residue R,
   with the proviso that at least one of residues R¹ to R⁴ and one of residues R⁵ and R⁶ represents an organic residue R,
   ii) at least one organic compound carrying one or two inorganic acid group(s), preferably one or two sulfonic acid group(s), one or two sulfuric acid group(s), one or two phosphonic acid group(s) or one or two phosphoric acid group(s), or a salt of said organic compound, wherein the molecular weight of the organic compound or the salt thereof is less than 1,000 g/mol, preferably less than 900 g/mol, more preferably less than 800 g/mol, even more preferably less than 700 g/mol, even more preferably less than 600 g/mol and even more preferably less than 500 g/mol;
   iii) at least one organic solvent, and
   iv) at least one oxidizing agent, preferably at least one organic, metal-free oxidizing agent, more preferably at least one organic peroxide;
II) oxidatively polymerizing the thiophene monomers for the formation a polythiophene, preferably for the formation of a cationic polythiophene, more preferably for the formation of a complex of a polythiophene and the organic compound ii) (which is preferably present in the form of an anion).

In an embodiment 2 of process 1 according to the invention, process 1 is designed according to its embodiment 1, wherein the organic residue R does not carry anionic groups. Preferably, residue R does not carry any sulfonic acid groups or salts of this group.

In an embodiment 3 of process 1 according to the invention, process 1 is designed according to its embodiment 1 or 2, wherein the organic residue R is selected from the group consisting of an alkyl group, an alkoxy group, an aryl group, an ether group and an ester group.

In an embodiment 4 of process 1 according to the invention, process 1 is designed according to anyone of its embodiments 1 to 3, wherein the reaction mixtures provided in process step I) comprises thiophene monomers of structure (VIa) or structure (VIb) in which X and Z represent O, preferably thiophene monomers of structure (VIa) in which X and Z represent O, and wherein three of the residues selected from the group consisting of R¹, R², R³ and R⁴ and one of the residues selected from the group consisting of R⁵ and R⁶ represent a hydrogen atom and the remaining residue represents an ether group having the structural formula (IIa)

—(CR⁷R⁸)ₙ—O—R⁹ (IIa)

wherein
R⁷ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁷ is H;
R⁸ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁸ is H;
n is an integer in the range from 0 to 10, preferably in the range from 1 to 6 and more preferably in the range from 1 to 3, wherein it is most preferred that n is 1; and
R⁹ is an alkyl group, an alkoxy group, an aryl group, an ether group or an ester group, preferably a C₁-C₃₀ alkyl group, more preferably a C₂-C₂₅-alkyl group, even more preferably a C₅-C₂₀-alkyl group.

In an embodiment 5 of process 1 according to the invention, process 1 is designed according to anyone of its embodiments 1 to 3, wherein the reaction mixtures provided in process step I) comprises thiophene monomers of structure (VIa) or structure (VIb) in which X and Z represent O, preferably thiophene monomers of structure (VIa) in which X and Z represent O, and wherein at least two of the residues selected from the group consisting of R¹, R², R³ and R⁴ and one of the residues selected from the group consisting of R⁵ and R⁶, preferably three of the residues selected from the group consisting of R¹, R², R³ and R⁴ and one of the residues selected from the group consisting of R⁵ and R⁶ represent a hydrogen atom and the remaining residues, preferably the remaining residue represent/s an alkyl group having formula (IIb)

—CₙH₂ₙ₊₁ (IIb)

wherein n is an integer in the range from 1 to 20, preferably in the range from 2 to 15, more preferably in the range from 3 to 15 and even more preferably in the range from 3 to 10. A particularly preferred alkyl group is an ethyl group, a n-propyl group, a n-butyl group, a n-pentyl group, a n-hexyl group, a n-heptyl group, a n-octyl group, a n-nonyl group or a n-decyl group, wherein an ethyl group, a n-butyl group and a n-decyl group are particularly preferred and wherein a n-butyl group is most preferred.

Suitable examples of monomer units of structure (Ia) carrying a branched alkyl group or more than one alkyl groups comprise a compound selected from the group consisting of compounds (A), (B), (C) and (D):

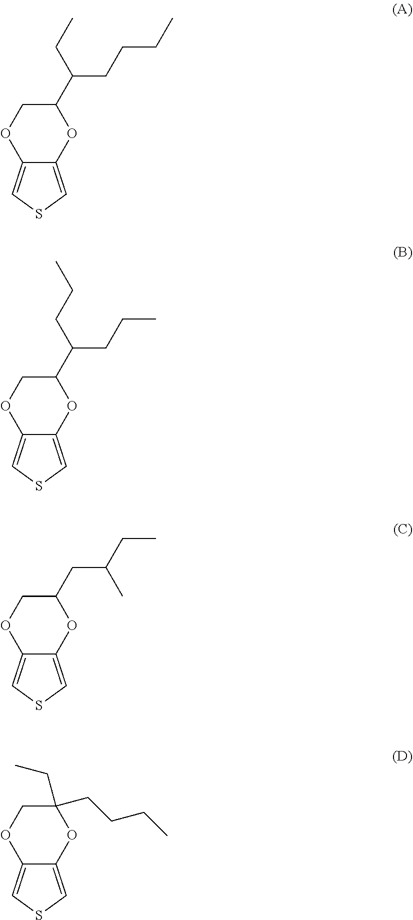

In an embodiment 6 of process 1 according to the invention, process 1 is designed according to anyone of its embodiments 1 to 3, wherein the reaction mixtures provided in process step I) comprises thiophene monomers of structure (VIa) or structure (VIb) in which X and Z represent O, preferably thiophene monomers of structure (VIa) in which X and Z represent O, and wherein three of the residues selected from the group consisting of R¹, R², R³ and R⁴ and one of the residues selected from the group consisting of R⁵ and R⁶ represent a hydrogen atom and the remaining residue represents a branched alkyl group or branched ether group, preferer ably a branched ether group, more preferably a branched ether group having the structural formula (IIc)

—(CR¹⁰R¹¹)ₙ—O—R¹² (IIc)

wherein
R¹⁰ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹⁰ is H;
R¹¹ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹¹ is H;
n is an integer in the range from 0 to 10, preferably in the range from 1 to 6 and more preferably in the range from 1 to 3, wherein it is most preferred that n is 1; and
R¹² is a branched organic residue, preferably a branched alkyl group or a branched arylalkyl group, more preferably a branched alkyl group or a branched arylalkyl group that do not carry an unsaturated C═C-bond in the alkyl chain, even more preferably an organic residue having formula (IId)

—(CHR¹³)ₘ—R¹⁴ (IId)
wherein
   m is 1, 2 or 3,
   R¹³ is H or a C₁-C₁₂ alkyl group, preferably a C₂-C₁₀ alkyl group and more preferably a C₃-C₈ alkyl group, even more preferably a butyl group, with the provisio that in only one of the m structural units —CHR¹³— residue R¹³ is a C₁-C₁₂ alkyl group;
   R¹⁴ is a C₁-C₁₀-alkyl group, preferably a C₂-C₆-alkyl group, or a aryl group.

In an embodiment 7 of the process 1 according to the invention, process 1 is designed according to its embodiment 6, wherein the polythiophene is a homopolymer or copolymer comprising monomer units selected from the group consisting of compounds (E), (F) and (G):

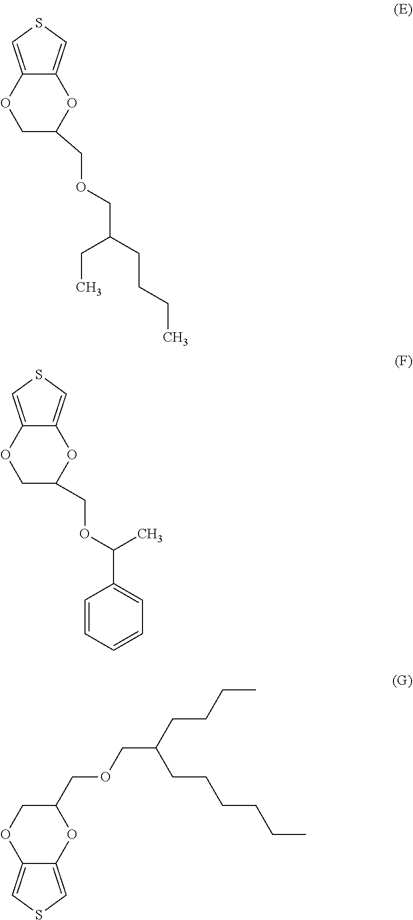

In connection with embodiment 6 and 7 of the process according to the present invention it may also be possible to use organic compounds as component ii) that carry more than two inorganic acid groups and the molecular weight of which is larger than 1,000 g/mol, such as polystyrene sulfonic acid (PSS).

In an embodiment 8 of process 1 according to the invention, process 1 is designed according to its embodiment 1 to 7, wherein the reaction mixture comprises as component i) 3,4-ethylenedioxythiophene and at least one derivative of 3,4-ethylenedioxythiophene having structural formula (VIa) in which X and Z represent O, wherein the at least one organic solvent iii) is an aprotic solvent iii) and wherein in process step II) the 3,4-ethylenedioxythiophene and the derivative of 3,4-ethylenedioxythiophenethiophene are oxidatively polymerized for the formation a copolymer. The reaction mixture provided in process step I) thus comprises as component i) 3,4-ethylenedioxythiophene and at least one derivative of 3,4-ethylenedioxythiophene in which at least one of the hydrogen atoms of the ethylene group is substituted by an organic residue R.

In an embodiment 9 of process 1 according to the invention, process 1 is designed according to its embodiment 8, wherein the derivative of 3,4-ethylenedioxythiophene has the structural formula (Ia′):

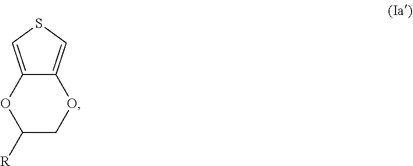

in which R is preferably selected from the group consisting of an alkyl group, an alkoxy group, an aryl group, an ether group and an ester group.

In an embodiment 10 of process 1 according to the invention, process 1 is designed according to its embodiment 9, wherein the organic residue R is an ether group.

In an embodiment 11 of process 1 according to the invention, process 1 is designed according to its embodiment 10, wherein the ether group has the structural formula (IIa)

—(CR⁷R⁸)ₙ—O—R⁹ (IIa)

wherein
R⁷ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁷ is H;
R⁸ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R⁸ is H;
n is an integer in the range from 0 to 10, preferably in the range from 1 to 6 and more preferably in the range from 1 to 3, wherein it is most preferred that n is 1; and
R⁹ is an alkyl group, an alkoxy group, an aryl group, an ether group or an ester group, preferably a C₁-C₃₀ alkyl group, preferably a C₂-C₂₅-alkyl group, more preferably a C₅-C₂₀-alkyl group.

In an embodiment 12 of process 1 according to the invention, process 1 is designed according to its embodiment 11, wherein the derivative of 3,4-ethylenedioxythiophene has the general formula (III)

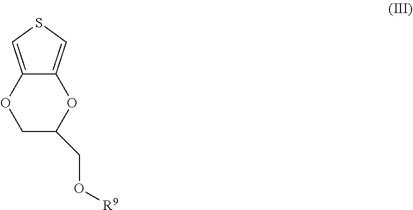

in which R⁹ is an alkyl group, an alkoxy group, an aryl group, an ether group or an ester group, preferably is a C₁-C₃₀ alkyl group, preferably a C₂-C₂₅-alkyl group, more preferably a C₅-C₂₀-alkyl group.

In an embodiment 13 of process 1 according to the invention, process 1 is designed according to its embodiment 12, wherein the derivative of 3,4-ethylenedioxythiophene has the general formula (IV)

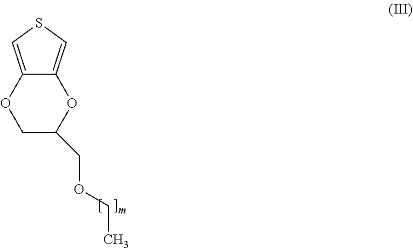

wherein m is an integer in the range from 0 to 24, preferably in the range from 1 to 19 and more preferably in the range from 4 to 14, wherein it is most preferred that m is 9.

In an embodiment 14 of process 1 according to the invention, process 1 is designed according to its embodiment 9, wherein the organic residue R is an alkyl group.

In an embodiment 15 of process 1 according to the invention, process 1 is designed according to its embodiment 14, wherein the alkyl group has formula (IIb)

—CₙH₂ₙ₊₁ (IIb)

wherein n is an integer in the range from 1 to 20, preferably in the range from 2 to 15, more preferably in the range from 3 to 15 and even more preferably in the range from 3 to 10. A particularly preferred alkyl group is an ethyl group, a n-propyl group, a n-butyl group, a n-pentyl group, a n-hexyl group, a n-heptyl group, a n-octyl group, a n-nonyl group or a n-decyl group, wherein an ethyl group, a n-butyl group and a n-decyl group are particularly preferred and wherein a n-butyl group is most preferred.

In an embodiment 16 of process 1 according to the invention, process 1 is designed according to its embodiment 15, wherein the derivative of 3,4-ethylenedioxythiophene has the general formula (V)

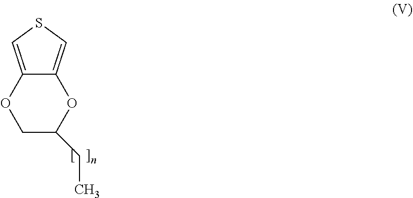

wherein n is in the range from 0 to 19, preferably in the range from 1 to 14 and more preferably in the range from 3 to 9. It is particularly preferred that n is 2, 3 or 4, wherein n=3 is most preferred.

In an embodiment 17 of process 1 according to the invention, process 1 is designed according to its embodiment 9, wherein the organic residue R is a branched alkyl group or a branched ether group, preferably a branched ether group, more preferably a branched ether group having the structural formula (IIc)

—(CR¹⁰R¹¹)ₙ—O—R¹² (IIc)

wherein
R¹⁰ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹⁰ is H;
R¹¹ is H, a C₁-C₁₀-alkyl group, preferably a C₁-C₅-alkyl group, more preferably a methyl group, or a C₁-C₁₀-alkoxy group, preferably a C₁-C₅-alkoxy group, more preferably a methoxy group, wherein it is most preferred that R¹¹ is H;
n is an integer in the range from 0 to 10, preferably in the range from 1 to 6 and more preferably in the range from 1 to 3, wherein it is most preferred that n is 1; and
R¹² is a branched organic residue, preferably a branched alkyl group or a branched arylalkyl group, more preferably a branched alkyl group or a branched arylalkyl group that do not carry an unsaturated C═C-bond in the alkyl chain, even more preferably an organic residue having formula (IId)

—(CHR¹³)ₘ—R¹⁴ (IId)
wherein
   m is 1, 2 or 3,
   R¹³ is H or a C₁-C₁₂ alkyl group, preferably a C₂-C₁₀ alkyl group and more preferably a C₃-C₈ alkyl group, even more preferably a butyl group, with the provisio that in only one of the m structural units —CHR¹³— residue R¹³ is a C₁-C₁₂ alkyl group;
   R¹⁴ is a C₁-C₁₀-alkyl group, preferably a C₂-C₆-alkyl group, or a aryl group.

In an embodiment 18 of process 1 according to the invention, process 1 is designed according to its embodiment 17, wherein the polythiophene is a homopolymer or copolymer comprising monomer units selected from the group consisting of compounds (E), (F) and (G):

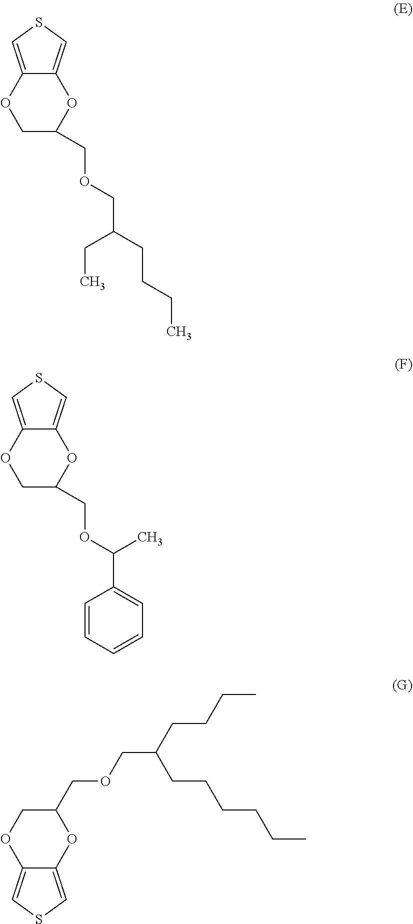

In an embodiment 19 of process 1 according to the invention, process 1 is designed according to anyone of its embodiments 1 to 18, wherein the reaction mixture provided in process step I) comprises the derivative of 3,4-ethylenedioxythiophene in a relative amount of 5 to 95%, preferably 10 to 80% and more preferably 20 to 60%, in each case based on the total molar amount of 3,4-ethylenedioxythiophene and derivative of 3,4-ethylenedioxythiophene.

In an embodiment 20 of process 1 according to the invention, process 1 is designed according to anyone of its embodiments 1 to 18, wherein the reaction mixture provided in process step I) comprises at least 30 wt.-%, preferably at least 40 wt.-% and more preferably at least 70 wt.-% monomer units that are based on the derivative of 3,4-ethylenedioxythiophene, in each case based on the total weight of monomer units (i.e. based on the total weight of 3,4-ethylenedioxythiophene-monomer units and monomer units based on the derivative of 3,4-ethylenedioxythiophene).

In an embodiment 21 of composition 1 according to the invention, composition 1 is designed according its embodiment 6, wherein the reaction mixture comprises as component i)
α) at least one derivative of 3,4-ethylenedioxythiophene having the structural formula structural formula (Ia′)

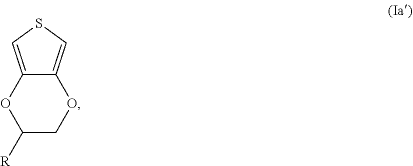

in which R is a branched alkyl group or a branched ether group, preferably a branched ether group, more preferably a branched ether group having the structural formula (IIc) as defined above,
β) at least one derivative of 3,4-ethylenedioxythiophene having the structural formula structural formula (Ia′)

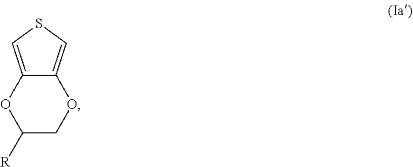

in which R is an alkyl group having the structural formula (IIb) as defined above, wherein a thiophene derivative selected from the group consisting of 2-ethyl-2,3-dihydrothieno[3,4-b]-1,4-dioxine, 2-propyl-2,3-dihydrothieno-[3,4-b]-1,4-dioxine 2-butyl-2,3-dihydrothieno[3,4-b]-1,4-dioxine, 2-decyl-2,3-dihydrothieno[3,4-b][1,4]dioxine is preferred and wherein 2-butyl-2,3-dihydrothieno[3,4-b]-1,4-dioxine (Butyl-EDOT) is particularly preferred,
   and optionally
γ) 3,4-ethylenedioxythiophene.

In an embodiment 22 of process 1 according to the invention, process 1 is designed according to its embodiment 21, wherein the reaction mixture comprises 5 to 99 mol.-%, preferably 15 to 70 mol-% and more preferably 30 to 50 mol-% monomer units that are based on monomers α), 5 to 95 mol-%, preferably 30 to 90 mol-% and more preferably 50 to 70 mol-% monomer units that are based on monomers β) and 0 to 50 mol-%, preferably 0 to 35 mol-% and more preferably 0 to 20 mol-% monomer units that are based on monomers γ), in each case based on the total amount of monomers α), β) and γ) in the reaction mixture, wherein the amounts of monomers α), β) and γ) sum up to 100 mol-%. According to a particularly preferred embodiment of process 1 the reaction mixture does not comprise 3,4-ethylenedioxythiophene as a comonomer.

In an embodiment 23 of process 1 according to the invention, process 1 is designed according to anyone of its embodiments 1 to 22, wherein in process step I), in process step II) or in both process steps the organic compound ii) is present in the form of the free acid.

In an embodiment 24 of of process 1 according to the invention, process 1 is designed according to anyone of its embodiments 1 to 23, wherein the inorganic acid group is a sulfonic acid group (—SO₂OH), a sulfuric acid group (—O—SO₂OH), a phosphonic acid group (—PO(OH)₂) or a phosphoric acid group (—O—PO(OH)₂), preferably a sulfonic acid group (—SO₂OH).

In an embodiment 25 of process 1 according to the invention, process 1 is designed according to anyone of its embodiments 1 to 24, wherein the organic compound ii) is an anionic surfactant.

In an embodiment 26 of process 1 according to the invention, process 1 is designed according to anyone of its embodiments 1 to 25, wherein the anionic surfactant is a sulfonic acid (R—SO₂OH), an ester of sulfuric acid (R—O—SO₂OH) or a salt of one of these anionic surfactants, preferably a salt of a sulfonic acid. In this context it is again particularly preferred that the anionic surfactant is a monovalent or divalent sulfonic acid (i.e. a compound that carries only a single sulfonic acid group or two sulfonic acid groups), most preferably a monovalent sulfonic acid.

In an embodiment 27 of process 1 according to the invention, process 1 is designed according to its embodiment 26, wherein the anionic surfactant is dodecylbenzene sulfonic acid or a salt thereof.

In an embodiment 28 of process 1 according to the invention, process 1 is designed according to anyone of its embodiments 1 to 27, wherein the weight ratio of the total amount of thiophene monomers (component i), preferably the total amount of 3,4-ethylenedioxythiophene and derivative of 3,4-ethylenedioxythiophene (component i) to the organic compound ii) in the reaction mixture provided in process step I) is in the range from 1:30 to 1:0.1, preferably in the range from 1:20 to 1:0.2 and more preferably in the range from 1:5 to 1:0.5.

In an embodiment 29 of process 1 according to the invention, process 1 is designed according to anyone of its embodiments 1 to 28, wherein the at least one organic solvent iii), preferably the at least one aprotic solvent iii), has a boiling point (determined at a pressure of 1013 mbar) in the range from 50 to 300° C., preferably in the range from 60 to 250° C. and more preferably in the range from 70 to 220° C.

In an embodiment 30 of process 1 according to the invention, process 1 is designed according to anyone of its embodiments 1 to 29, wherein the at least one organic solvent is an aprotic solvent iii), more preferably is a polar aprotic solvent.

In an embodiment 31 of process 1 according to the invention, process 1 is designed according to its embodiment 30, wherein the dielectric constant of the polar aprotic solvent iii) is less than 20, preferably less than 10 and more preferably less than 7.

In an embodiment 32 of process 1 according to the invention, process 1 is designed according to its embodiments 30 or 31, wherein the polar aprotic solvent iii) has a dipole moment of less than 4 D, preferably less than 2 D and more preferably less than 1.5 D.

In an embodiment 33 of process 1 according to the invention, process 1 is designed according to anyone of its embodiments 1 to 32, wherein the at least one organic solvent iii) is selected from the group consisting of aromatic hydrocarbons, esters, ethers, alcohols and mixtures thereof.

In an embodiment 34 of process 1 according to the invention, process 1 is designed according to its embodiment 33, wherein the at least one organic solvent iii) is selected from the group consisting of toluene, xylene, anisole, methyl benzoate, ethyl benzoate, propyl benzoate, butyl benzoate, methyl acetate, ethyl acetate, propyl acetate, butyl acetate, octyl acetate, methyl propionate, ethyl propionate, propyl propionate, butyl propionate, 1-methoxy-2-propylacetat, 1-methoxy-2-propanol, butanol, 2-propanol, ethanol and mixtures thereof or mixtures of one or two of these aprotic solvents with one or two further solvents. In case of a mixture of two or more organic solvents, it is particularly preferred that at least one of these solvents is an aprotic solvent iii).

In an embodiment 35 of the process according to the invention, process 1 is designed according to anyone of its embodiments 1 to 34, wherein process 1 comprises the further step of:
III) adding an additive v) that is different from the monomers i), the anion ii), the aprotic solvent iii) and the oxidizing agent iv) to the reaction mixture provided in process step I).

In an embodiment 36 of the process according to the invention, process 1 is designed according to anyone of its embodiments 1 to 35, wherein process 1 comprises the further step of:
IV) diluting the composition obtained after process step II), or optionally obtained after process step III) or after process step IV), with a further organic solvent vi) that is different from solvent iii).

In an embodiment 37 of the process according to the invention, process 1 is designed according to its embodiment 36, wherein the weight ratio of the composition to the further solvent vi) is in the range from 50:1 to 0.02:1.

In an embodiment 38 of the process according to the invention, process 1 is designed according to its embodiment 36 or 37, wherein the further organic solvent vi) is organic solvent, preferably an aprotic solvent, as defined in anyone of embodiments 31 to 37 of process 1.

In an embodiment 39 of process 1 according to the invention, process 1 is designed according to anyone of its embodiments 1 to 38, wherein the composition provided in process step I) comprises
i) a total amount of 0.01 to 20 wt.-%, preferably 0.02 to 10 wt.-% and more preferably 0.1 to 5 wt.-% of thiophene monomers having structure (VIa) or (VIb), preferably a total amount within these ranges of 3,4-ethylenedioxythiophene and derivative of 3,4-ethylenedioxythiophene (these amounts thus corresponding to the total weight of 3,4-ethylenedioxythiophene and derivative of 3,4-ethylenedioxythiophene);
ii) 0.01 to 15 wt.-%, preferably 0.02 to 10 wt.-% and more preferably 0.1 to 5wt.-% of the organic compound;
iii) 50 to 99.98 wt.-%, preferably 70 to 99.86 wt.-% and more preferably 85 to 99.3 wt.-% of the solvent or solvent mixture, preferably the aprotic solvent or solvent mixture;
iv) 0.01 to 15 wt.-%, preferably 0.1 to 10 wt.-% and more preferably 0.5 to 5 wt.-% of an additive being different from components i) to iv);
   wherein the total weight of components i) to v) sums up to 100 wt.-%.

In an embodiment 40 of process 1 according to the invention, process 1 is designed according to anyone of its embodiments 1 to 39, wherein process 1 comprises the further step of:
V) adding a non-conductive oligomer or polymer to the product obtained in process step II), III) or IV), preferably a non-conductive oligomeric or polymeric binder.

In an embodiment 41 of process 1 according to the invention, process 1 is designed according to its embodiment 40, wherein the non-conductive polymeric binder is selected from the group consisting of a polyolefin, a polyvinyl acetate, a polycarbonate, a poly(meth)acrylate, a polyvinyl butyral, a poly(meth)acrylic acid amide, a polystyrene, a polyacrylonitrile, a polyvinyl chloride, a polyvinyl pyrrolidone, a polybutadiene, a polyisoprene, a polyether, a polyester, a polyurethane, a polyamide, a polyimide, a polysulphone, a polysilicone, an epoxy resin, a styrene-acrylate, a vinyl acetate/acrylate or an ethylene/vinyl acetate copolymer, a polyvinyl alcohol, a cellulose derivative or a mixture comprising at least two of these polymers, wherein a poly(meth)acrylate and a polysilicone area particularly preferred non-conductive polymeric binders. Also suitable as non-conductive polymeric binders are multifunctional (meth)acrylates such as dipentaerythritol penta-/hexaacrylate.

In an embodiment 42 of process 1 according to the invention, process 1 is designed according to its embodiment 41, wherein the poly(meth)acrylate is selected from the group consisting of poly(methyl acrylate), poly(methyl methacrylate), poly(ethyl acrylate), poly(ethyl methacrylate), poly(n-propyl acrylate), poly(n-propyl methacrylate), poly(isopropyl acrylate), poly(isopropyl methacrylate), poly(n-butyl acrylate), poly(n-butyl methacrylate), poly(isobutyl acrylate), poly(isobutyl methacrylate), poly(tert.-butyl acrylate), poly(tert.-butyl methacrylate), poly(2-ethylhexyl acrylate), poly(2-ethylhexyl methacrylate), poly(cyclohexyl acrylate), poly(cyclohexyl methacrylate), poly(phenyl acrylate), poly(phenyl methacrylate), poly(benzyl acrylate), poly(benzyl methacrylate) and copolymers of these polyacrylates or polymethacrylates.

In an embodiment 43 of process 1 according to the invention, process 1 is designed according to anyone of its embodiments 40 to 42, wherein the non-conductive polymeric binder, preferably the poly(meth)acrylate and/or the polysilicone, is/are added in such an amount that the non-conductive polymeric binder and the polythiophene/organic compound complex are present in a mass ratio of at least 20:1, preferably at least 25:1 and more preferably at least 30:1.

In an embodiment 44 of process 1 according to the invention, process 1 is designed according to anyone of its embodiments 1 to 43, wherein the reaction mixture provided in process step I) comprises less than 2 wt.-%, preferably less than 1 wt.-% and most preferably less than 0.1 wt.-% water, based on the total weight of the composition.

A contribution to solving at least one of the objects according to the invention is also made by an embodiment 1 of a composition 2, obtainable by process 1 according to anyone of its embodiments 1 to 44.

A contribution to solving at least one of the objects according to the invention is also made by an embodiment 1 of a layer structure 1 comprising a substrate and an electrically conductive layer applied onto the substrate, wherein the electrically conductive layer comprises
i) at least one polythiophene comprising monomer units of structure (Ia) or (Ib)

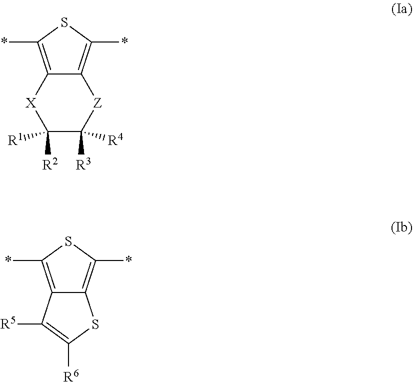

in which
   * indicates the bond to the neighboring monomer units,
   X,Z represent O or S,
   R¹-R⁶ independently from each other represent a hydrogen atom or an organic residue R,
with the proviso that at least one of residues R¹ to R⁴ and one of residues R⁵ and R⁶ represents an organic residue R, preferably at least one copolymer of 3,4-ethylenedioxythiophene and at least one derivative of 3,4-ethylenedioxythiophene in which at least one of the hydrogen atoms of the ethylene group is substituted by an organic residue R;
ii) at least one organic compound carrying one or two inorganic acid group(s), preferably one or two sulfonic acid group(s), one or two sulfuric acid group(s), one or two phosphonic acid group(s) or one or two phosphoric acid group(s), or a salt of said organic compound, wherein the molecular weight of the organic compound or the salt thereof is less than 1,000 g/mol, preferably less than 900 g/mol, more preferably less than 800 g/mol, even more preferably less than 700 g/mol, even more preferably less than 600 g/mol and even more preferably less than 500 g/mol.

Preferred polythiophenes or copolymers i) and anions ii) are those polythiophenes or copolymers and anions, that have already been described in connection with composition 1 and process 1 according to the invention.

In an embodiment 2 of layer structure 1 according to the invention, layer structure 1 is designed according its embodiment 1, wherein the weight ratio of polythiophene i), preferably of copolymer i), to organic compound ii) or the salt thereof in the electrically conductive layer is in the range from 1:30 to 1:0.1, preferably in the range from 1:20 to 1:0.2 and more preferably in the range from 1:5 to 1:0.5.

In an embodiment 3 of layer structure 1 according to the invention, layer structure 1 is designed according its embodiment 1 or 2, wherein the electrically conductive layer further comprises
iii) a non-conductive oligomer or polymer, preferably a non-conductive oligomeric or polymeric binder,
   wherein preferred non-conductive oligomeric or polymeric binders are those that have already been mentioned in embodiments 37 to 39 of composition 1 according to the present invention.

In an embodiment 4 of layer structure 1 according to the invention, layer structure 1 is designed according to its embodiment 3, wherein the electrically conductive layer comprises the non-conductive polymeric binder iv), preferably the poly(meth)acrylate and/or the polysilicone, and the polythiophene/organic compound complex i)/ii) in a mass ratio of at least 20:1, preferably at least 25:1 and more preferably at least 30:1.

In an embodiment 5 of layer structure 1 according to the invention, layer structure 1 is designed according to its embodiment 3 or 4, wherein the electrically a conductive layer has a sheet resistance of at most 1×10¹⁰ Ohm/sq, preferably at most 5×10⁹ Ohm/sq and more preferably of at most 1×10⁸ Ohm/sq.

A contribution to solving at least one of the objects according to the invention is also made by an embodiment 1 of a process 2 for the preparation of a layer structure, comprising the process steps of
A) provision of a substrate;
B) coating a substrate with composition 1 according to anyone of its embodiments 1 to 44 or with composition 2 according to its embodiment 1;
C) at least partial removal of the organic solvent iii), preferably the aprotic solvent iii), for the formation of an electrically conductive layer.

In an embodiment 2 of process 2 according to the invention, process 2 further comprises the step of
D) applying an intermediate coating, such as an adhesive layer or a primer layer, onto the substrate before performing process step B).

A contribution to solving at least one of the objects according to the invention is also made by an embodiment 1 of a layer structure 2, obtainable by process 2 according to the invention.

In an embodiment 2 of layer structure 1 or layer structure 2 according to the invention, the layer structure is designed according its corresponding embodiment 1, wherein the electrically conductive layer has a conductivity of at least 1 S/cm, preferably at least 2 S/cm and most preferably at least 5 S/cm.

A contribution to solving at least one of the objects according to the invention is also made by an embodiment 1 of an electronic component, in particular an organic light-emitting diodes, an organic solar cells or a capacitors, comprising a layer structure 1 according to its embodiment 1 or 2 or a layer structure 2 according to its embodiment 1.

A contribution to solving at least one of the objects according to the invention is also made by the use of composition 1 according to anyone of its embodiments 1 to 46 or of composition 2 according to its embodiment 1 to produce an electrically conductive layer in an electronic component, in particular in organic light-emitting diodes, organic solar cells or capacitors or to produce an antistatic coating.

Organic Compound ii)

The organic compound carrying one or two inorganic acid groups i) or the salt thereof that is present in the composition or the layer structure according to the invention or that is present in the reaction mixture that is provided in process step I) of the process according to the invention preferably is an anionic surfactant, wherein it is furthermore preferred that the anionic surfactant is selected from the group consisting of organic phosphonic acids, organic phosphoric acids, organic sulfonic acids such as sulfonic acids, such as alkyl-aryl-sulfonic acids, alkyl sulfates, alkyl sulfonates, alkyl ether sulfates, and salts or mixtures thereof. Each of the following anionic surfactants may contain a mixture of compounds varying in the length of the alkyl chain:
Suitable alkyl sulfates include, but are not limited to, C₈-C₁₈ alkyl sulfates such as sodium dodecyl sulfate, lithium dodecyl sulfate, ammonium dodecyl sulfate, sodium tetradecyl sulfate, sodium 7-ethyl-2-methyl-4-undecyl sulfate and sodium 2-ethylhexyl sulfate.
Suitable alkyl ether sulfates include, but are not limited to, C₈-C₁₈ alkyl ether sulfates such as sodium laureth sulfate and sodium myreth sulfate.
Suitable alkyl sulfonates include, but are not limited to, C₈-C₁₈ alkyl sulfonates such as sodium tetradecyl sulfonate, sodium octadecyl sulfonate, sodium dodecyl sulfonate, sodium hexadecyl sulfonate and the corresponding sulfonic acids.
Suitable aryl sulfonates or sulfonic acids, optionally substituted with alkyl or aryl substituents include, but are not limited to, C₂-C₁₈ alkylbenzene sulfonates or sulfonic acids such as sodium dodecylbenzene sulfonate, dodecylbenzene sulfonic acid, ethylbenzene sulfonic acid and dodecylbenzene sulfonic acid isopropylamine salt; C₂-C₁₈ alkyl naphthalene sulfonates or sulfonic acids such as sodium butyl naphthalene sulfonate and sodium hexyl naphthalene sulfonate, especially sodium dodecylbenzene sulfonate or dodecylbenzene sulfonic acid. If optionally substituted with an alkyl substituent, the aryl sulfonate or sulfonic acid may be positioned at any point along the alkyl chain, for example on a primary, secondary or tertiary carbon. Suitable alkyl ester sulfonates or sulfonic acids include, but are not limited to, C₂-C₁₈ alkyl methyl ester sulfonates or sulfonic acids such as methyl ester sulfonate, sodium dodecyl methyl ester α-sulfonate, sodium tetradecyl methyl ester α-sulfonate and sodium hexadecyl methyl ester α-sulfonate. The sulfate, sulfonate or sulfonic acid groups may be positioned at any point along the alkyl chain or aryl ring, for example on a primary, secondary or tertiary carbon.
Also suitable are surfactants carrying two sulfonic acid groups such as C₂-C₁₆ alkyl diphenyl oxide disulfonates or disulfonic acids such as sodium dodecyl diphenyloxide disulfonate.
Suitable organic phosphonic acids include monovalent phosphonic acids such as phenyl phosphonic acid, 11-hydroxyundecyl phosphonic acid, 2,4-xylyl phosphonic acid, 4-ethylphenyl phosphonic acid, octyl phosphonic acid, octadecyl phosphonic acid, undecyl phosphonic acid, dodecyl phosphonic acid, p-(diphenylmethyl) phosphonic acid, 11-phosphono undecanoic acid and p-(1-naphthalenylmethyl) phosphonic acid, or diphosphonic acids such as (12-phosphonododecyl) phosphonic acid and 1,8-octane diphosphonic acid.

It is, however, particularly preferred that the anionic surfactant is a monovalent sulfonic acid, particularly preferred dodecylbenzene sulfonic acid or a salt thereof.

Additives iv)

Suitable additives iv) which can also be present in the composition according to the present invention include oxidizing agents (preferably in their reduced form), conductivity-improving agent, adhesion promoters, binders and crosslinking agents:
Additives which enhance the conductivity comprise compounds such as for example tetrahydrofuran, lactone group-comprising compounds such as butyrolactone, valerolactone, amide group- or lactam group-comprising compounds such as caprolactam, N-methyl caprolactam, N,N-dimethyl acetamide, N-methyl acetamide, N,N-dimethyl formamide (DMF), N-methyl formamide, N-methyl formanilide, N-methyl pyrrolidone (NMP), N-octyl pyrrolidone, pyrrolidone, sulphones and sulphoxides, such as for example sulpholane (tetramethylene sulphone), dimethyl sulphoxide (DMSO), sugar or sugar derivatives, such as for example sucrose, glucose, fructose, lactose, sugar based surfactants such as Tween or Span 60, sugar alcohols such as for example sorbitol, mannitol, furan derivatives such as for example 2-furan carboxylic acid, 3-furan carboxylic acid, and/or di- or polyalcohols such as for example ethylene glycol, glycerol or di- or triethylene glycol. Tetrahydrofuran, N-methyl formamide, N-methyl pyrrolidone, ethylene glycol, dimethyl sulphoxide or sorbitol are particularly preferably used as conductivity-raising additives.
Suitable adhesion promoters are compounds such as e.g. organofunctional silanes or hydrolysates thereof, e.g. 3-glycidoxypropyltrialkoxysilane, 3-aminopropyltriethoxysilane, 3-mercaptopropyltrimethoxysilane, 3-methacryloxypropyltrimethoxysilane, vinyltrimethoxysilane or octyltriethoxysilane.
Binders comprise organic binders which in particular are soluble in organic solvents, such as polyolefins, polyvinyl acetate, polycarbonate, polyvinyl butyral, polyacrylic acid esters, polyacrylic acid amides, polymethacrylic acid esters, polymethacrylic acid amides, polystyrene, polyacrylonitrile, polyvinyl chloride, polyvinyl pyrrolidones, polybutadiene, polyisoprene, polyethers, polyesters, polyurethanes, polyamides, polyimides, poly sulphones, polysilicones, epoxy resins, styrene-acrylate, vinyl acetate/acrylate and ethylene/vinyl acetate copolymers, polyvinyl alcohols or cellulose derivatives, can also be added to the composition. Also suitable as binders are copolymers of the above mentioned polymers. Particular in the case of polythiophenes comprising thiophene monomers carrying an alky group as residue R it is particularly preferred that the composition further comprises a non-conductive oligomeric or polymeric binder, particularly a poly(meth)acrylate and/or a polysilicone.
Suitable crosslinking agents comprise melamine compounds, capped isocyanates, functional silanes, for example tetraethoxysilane, alkoxysilane hydrolysates for example based on tetraethoxysilane, or epoxysilanes such as 3-glycidoxypropyl trialkoxysilane.

Process for Producing the Composition According to the Present Invention

In the process according to the invention the thiophene monomers are oxidatively polymerised in the presence of the organic compound ii) (which is preferably present in the form of an anion) and the aprotic solvent iii). The oxidising agents iv) that are suitable for the oxidative polymerisation of pyrrole can be used as oxidising agents. For practical reasons, inexpensive and easy-to-handle oxidising agents can be used, for example iron(III) salts such as FeCl₃, Fe(ClO₄)₃ and the iron(III) salts of organic acids and of inorganic acids comprising organic radicals. The iron(III) salts of sulphuric acid hemiesters of C₁-C₂₀ alkanols, for example the Fe(III) salt of lauryl sulphate, are cited by way of example as iron(III) salts of inorganic acids comprising organic radicals. The following are cited by way of example as iron(III) salts of organic acids: the Fe(III) salts of C₁-C₂₀ alkyl sulphonic acids, such as methane- and dodecane-sulphonic acid; aliphatic C₁-C₂₀ carboxylic acids such as 2-ethylhexyl carboxylic acid; aliphatic perfluorocarboxylic acids, such as trifluoroacetic acid and perfluorooctanoic acid; aliphatic dicarboxylic acids such as oxalic acid and above all of aromatic sulphonic acids optionally substituted with C₁-C₂₀ alkyl groups, such as benzenesulphonic acid, p-toluenesulphonic acid and dodecylbenzenesulphonic acid. The iron(III) salts of organic acid have the big applicational advantage that they are partially or completely soluble in organic solvents and in particular in water-immiscible organic solvents. Organic peroxides such as for example tert-butyl peroxide, diisobutyryl peroxide, di-n-propyl peroxydicarbonate, didecanoyl peroxide, dibenzoyl peroxide, tert-butyl peroxybenzoate, di-tert-amyl peroxide can also be used as oxidising agents. Organic azo compounds such as for example 2,2′-azodiisobutyronitrile can also be used. Particularly preferred oxidizing agents are organic, metal-free oxidizing agents such as organic peroxides, wherein dibenzoyl peroxide is most preferred.

Theoretically, for the oxidative polymerization of the thiophene monomers, per mole of thiophene, 2.25 equivalents of oxidizing agent are needed (see e.g. J. Polym. Sc., Part A, Polymer Chemistry, vol. 26, p. 1287 (1988)). However, in the prior art, the oxidising agent is normally used in a certain excess amount, e.g. an excess of 0.1 to 2 equivalents per mole of thiophene.

In process step II) of the process according to the invention, the thiophene monomers are oxidatively polymerized—in the presence of the organic compound ii)—by reduction of the oxidising agent to a reduction product and oxidation of the thiophene monomer, to form a composition preferably comprising cationic polythiophene-copolymers i) and the reduction product, wherein said polymerization preferably takes place at a temperature in the range from 0° C. to 100° C. In this context it is particularly preferred that the reaction temperature is in a range from 25° C. up to a temperature that is below the lowest boiling point of the solvents comprised in the reaction mixture.

The anions ii) that are present in the reaction mixture provided in process step I) serve as counterions to compensate that positive charge of the polythiophenes i), preferably of the copolymers i). Anions ii) and polythiophenes i) are preferably present in the form of a polythiophene/anion-complex. In this context it is also preferred that in process step II) a composition is obtained that comprises the polythiophene i) and the anions ii) in the form of such a complex, wherein it is particularly preferred that the composition is present in the form of a dispersion comprising the aprotic solvent iii) in which this complex is dispersed.

The invention is now described in more detail by reference to figures, test methods and non-limiting examples.

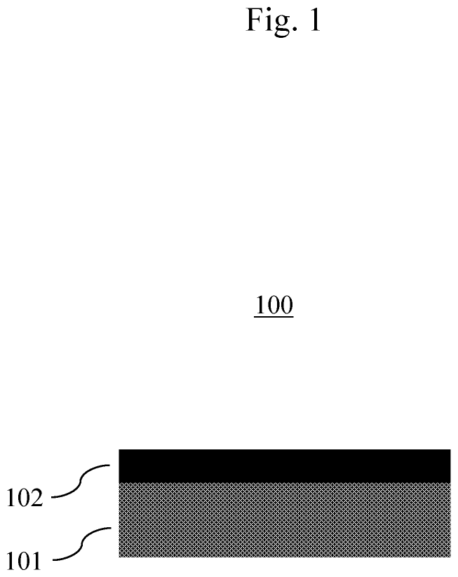

FIG. 1 shows the structure of a layer structure 100 according to the invention, for example an antistatic film, in general form. On the substrate surface of a substrate 101, in the case of an antistatic film often a PE, PP or PET layer, is an electrically conductive layer 102 that has been prepared with the composition according to the invention.

Test Methods

Determination of the Conductivity

The electrical conductivity means the inverse of the specific resistance. The specific resistance is calculated from the product of surface resistance and layer thickness of the conductive polymer layer. The surface resistance is determined for conductive polymers in accordance with DIN EN ISO 3915. In concrete terms, the composition to be investigated is applied as a homogeneous film by means of a spin coater to a glass substrate 50 mm×50 mm in size thoroughly cleaned by the above-mentioned substrate cleaning process. In this procedure, the coating composition is applied to the substrate by means of a pipette to completely cover the area and spun off directly by spin coating. The spin conditions for coating compositions were 20 s at approx. 1,000 rpm in air. Thereafter, a drying process on a hot-plate was carried out (10 min at 130° C. in air). Silver electrodes of 2.0 cm length at a distance of 2.0 cm are vapour-deposited on to the polymer layer via a shadow mask. The square region of the layer between the electrodes is then separated electrically from the remainder of the layer by scratching two lines with a scalpel. The surface resistance is measured between the Ag electrodes with the aid of an ohmmeter (Keithley 614). The thickness of the polymer layer is determined with the aid of a Stylus Profilometer (Dektac 150, Veeco) at the places scratched away.

Determination of the Water Content

The water content of the composition according to the present invention can be determined by means of a Karl Fischer titration. A Metrohm 787 KF Titrino with a 703 titration stand is used to this end. The titration vessel is filled with analytical-grade methanol so that about 1 cm of the platinum electrode is submerged. Then approximately 5 ml of Hydranal buffer acid is pipetted in. The titration cell is automatically dried by starting the KFT program. Preparation is complete when the message “KFT conditioned” appears. Approximately 5 ml of the composition to be analysed is then introduced into the titration vessel using a syringe and the exact mass of the dispersion used is determined by back-weighing the syringe. The titration is then started. The measured value is determined as the mean of three individual measurements.

Solids Content

The solid content was determined by gravimetry using a precision scale (Mettler AE 240). First the empty weighing bottle including lid is weight in (Weight A). Then ca. 3 g of dispersion to be analysed is filled quickly into the bottle, closed by the lid and weighed again to determine the exact total weight B. The bottle is then placed in a fume hood without a lit for ca. 3 hours to allow the evaporation of volatile solvents at room temperature. In a second step the bottle is placed in a drying oven with ventilation (Memmert UNB200) at 160° C. for 16-17 hours. When the sample bottle is removed from the oven, immediate coverage by the glass lid is important due to the hygroscopic nature of the dry dispersion material. After 10-15 min of cooling down period the bottle is weighed again including lid to determine weight C.

Calculation of the solid contents: wt. % solids content=100×(C−A)/(B−A)

The result is the average of two measurement.

Preparation of Films on PET Substrates

The dispersion was applied to a PET substrate at room temperature using manual doctor blades from Erichsen which had a gap separation of 12 μm. The gap separation of the manual doctor blade in this context determines the thickness of the wet film formed, which is also called the wet film thickness. The coatings or films formed in this way were then dried in a drying oven at 130° C. for 5 min. Before any further processing, the coated PET substrate was cooled to room temperature.

Determination of the Surface Resistivity

The surface resistivity was measured with a Staticide ACL 800 Digital Megohmmeter at the 100 V setting. Two measurements on different positions on the sheet were conducted and the lowest value was taken as the result. The highest measurable surface resistivity is 2×10¹¹ Ω/sq. Values at or above that threshold are considered out of range but will still be displayed at 2×10¹¹ Ω/sq.

Determination of the dispersion's stability in organic solvents

The dispersion's stability was determined by slowly adding the mentioned amount of solvent to the initial dispersion over the course of 5 minutes. The mixture was stirred slowly during the process of the solvent addition and for an additional 15 minutes. The mixture was stored at room temperature for 24 h without any mechanical disturbance. The resulting mixtures were classified into three categories after visual assessment:

+ stable, homogenous dispersion without any particles

0 small particles visible

− large particles and/or significant gelation and/or phase separation

### EXAMPLES

### Example 1

### Reference Example for the Synthesis of 2-[(decyloxy)methyl]-2,3-dihydrothieno[3,4-b]-1,4-dioxin

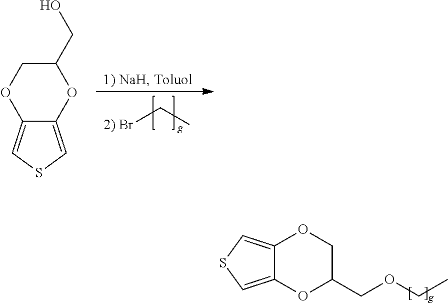

The synthesis is conducted under dry and inert conditions.

THF (6.6 L) and 18-Crown-6 (22.0 g, 88 mmol) are added to the reaction vessel. NaH (166.4 g, 4.15 mol) as 60% suspension in oil is added under stirring, the mixture is stirred at room temperature. At 0° C. a EDOT-MeOH (551 g, 3.2 mol) solution in THF are added to the NaH solution. After addition of the solution the reaction mixture is stirred for 1.5 h at room temperature, subsequently 1 h at 50° C. Reaction mixture is cooled to 0° C. and a 1-bromo-decane (936.7 g, 4.2 mol) solution, stirred for 1 h at room temperature and 15 h at 50° C. The reaction mixture is cooled to room temperature and quenched with a mixture of isopropanol/water 70:30 (v/v). The crude product was purified by column chromatography.

The reaction product (2-[(decyloxy)methyl]-2,3-dihydro-thieno[3,4-b]-1,4-dioxin, CAS: 210476-55-4) is obtained as a yellow oil in a yield of 74-80%.

### Example 2

### Comparative Example According to the Teaching of WO-A-2012/059215

A 1 L three-necked round-bottom flask equipped with mechanical stirrer was charged with 294 g anisole (Aldrich), 9.4 g of dibenzoyl peroxide (39 mmol; Aldrich), 8.25 g of a sulfonated block-copolymer (Kraton Nexar® MD) and 7.2 g of para-toluene sulfonic acid (38 mmol, Aldrich). After heating to 60° C. 4.95 g of 3,4-ethylenedioxythiophene (35 mmol; Clevios M V2; Heraeus Deutschland GmbH & Co KG, Germany) dissolved in 20 g of anisole were added over 40 min. The dispersion was stirred for another 3 h at 60° C. and then cooled to room temperature. This dispersion is called dispersion 2A.

20 g of the dispersion obtained after filtration and 20 g of butyl acetate were mixed in a 50 ml glass bottle and subjected to 2 min or ultrasound treatment (Hielscher UP 200 S, cycle 1, amplitude 100%). This sample is called dispersion 2B.

Analysis of Dispersion 2B:

Solids content: 2.5% (gravimetric)

Using a wire-bar a 12 μm wet film was deposited of dispersion 2B on a substrate and dried for 15 min at 130° C. in an oven. The conductive layer was characterized by the following properties:

Conductivity (on glass): 7.7 S/cm

Sheet resistance (12 μm on PET): 17,000 Ohm/sq

### Example 3

### According to the Present Invention

In Example 3 the following complex is prepared:

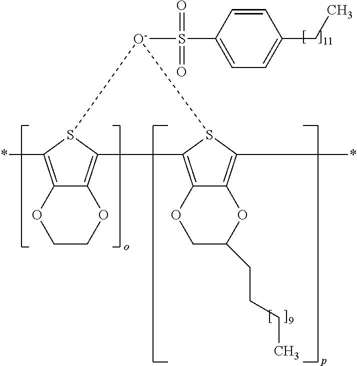

Dispersion A:

A 100 ml three-necked round-bottom flask equipped with mechanical stirrer, condenser and nitrogen inlet was charged with 29.7 g anisole (Aldrich), 2.7 g of dibenzoyl peroxide (11.1 mmol; Aldrich) and 3.7 g dodecylbenzene sulfonic acid (11.5 mmol; Aldrich). After heating to 60° C. 0.705 g of 3,4-ethylenedioxythiophene (5 mmol; Clevios M V2; Heraeus Deutschland GmbH & Co KG, Germany) and 1.55 g of the EDOT-derivative obtained in the Example 1(5 mmol) were added. The dispersion was stirred for another 3 h at 60° C. under nitrogen. Then 35 g of anisole were added. After cooling to room temperature, the dispersion was let to stand overnight. This dispersion is called dispersion 3A.

Dispersion 3B:

5 g of dispersion 3A and 5 g butyl acetate were mixed in a 20 ml glass bottle and subjected to 1 min of ultrasound treatment (Hielscher UP 200 S, cycle 1, amplitude 100%). This material is called dispersion 3B.

Analysis of Dispersion 3B:

Solids content: 2.4% (gravimetric)

Using a wire-bar a 12 um wet film was deposited on a PET substrate and dried for 15 min at 130° C. in an oven. The film was characterized by the following properties:

Sheet resistance (12 μm on PET) 20,000 Ohm/sq

Dispersion 3C:

2.5 g of dispersion+3A, 2.5 g anisole and 5 g butyl acetate were mixed in a 20 ml glass bottle and subjected to 1 min of ultrasound treatment (Hielscher UP 200 S, cycle 1, amplitude 100%). This material is called dispersion 3C.

Analysis of Dispersion 3C:

Solids content: 1.2% (gravimetric)

Water content: 0.04%

Ion-content was measured by inductively coupled plasma optical emission spectrometry:

Na content: 24 ppm

Ca content: 0.6 ppm

Mg content: 0.06 ppm

K, Fe, Cu, Pb, Al, Cr, Co, Mn, Ni, V, Zn and Cd were below the detection limit of 0.025 ppm.

Using a wire-bar a 12 μm wet film was deposited on a PET substrate and dried for 15 min at 130° C. in an oven. The film was characterized by the following properties:

Sheet resistance (12 μm on PET) 16,000 Ohm/sq

Transmission (including PET) 83.3%

Haze (including PET) 0.58

Dispersion 3C was deposited on glass by spin-coating and dried for 10 min at 130° C. on a hot plat. The conductivity was measured according to the Test method described above.

The film was characterized by the following property

Conductivity 9.4 S/cm

### Example 4

### According to the Present Invention

(in Example 4 the concentration of dodecylbenzenesulfonic acid is reduced)

A 100 ml three-necked round-bottom flask equipped with mechanical stirrer, condenser and nitrogen inlet was charged with 29.7 g anisole (Aldrich), 2.7 g of dibenzoyl peroxide (11.1 mmol; Aldrich) and 3.08 g dodecylbenzene sulfonic acid (9.6 mmol; Aldrich). After heating to 60° C. 0.705 g of 3,4-ethylenedioxythiophene (5 mmol; Clevios M V2; Heraeus Deutschland GmbH & Co KG, Germany) and 1.55 g of the EDOT-derivative obtained in the Example 1 (5 mmol) were added. The dispersion was stirred for another 3 h at 60° C. under nitrogen. Then 35 g of anisole were added. After cooling to room temperature, the dispersion was let to stand overnight. This dispersion is called dispersion 4A.

5 g of dispersion 4A, and 5 g butyl acetate were mixed in a 20 ml glass bottle and subjected to 1 min of ultrasound treatment (Hielscher UP 200 S, cycle 1, amplitude 100%). This material is called dispersion 4C.

Analysis of dispersion 4C:

Solids content: 2.1% (gravimetric)

Using a wire-bar a 12 μm wet film was deposited on a PET substrate and dried for 15 min at 130° C. in an oven. The film was characterized by the following properties:

Sheet resistance (12 μm on PET): 12,000 Ohm/sq

### Example 5

### According to the Present Invention

(in Example 5 the concentration of dodecylbenzenesulfonic acid is reduced further)

A 100 ml three-necked round-bottom flask equipped with mechanical stirrer, condenser and nitrogen inlet was charged with 29.7 g anisole (Aldrich), 2.7 g of dibenzoyl peroxide (11.1 mmol; Aldrich) and 2.2 g dodecylbenzene sulfonic acid (6.8 mmol; Aldrich). After heating to 60° C. 0.705 g of 3,4-ethylenedioxythiophene (5 mmol; Clevios M V2; Heraeus Deutschland GmbH & Co KG, Germany) and 1.55 g of the EDOT-derivative obtained in the Example 1 (5 mmol) were added. The dispersion was stirred for another 3 h at 60° C. under nitrogen. Then 35 g of anisole were added. After cooling to room temperature, the dispersion was let to stand overnight. This dispersion is called dispersion 5A.

### Example 6

Dispersion 2A and dispersion 5A were compared with respect to their solvent compatibility. Samples were mixed with additional solvent as shown in Table 1 and then subjected to ultrasound for 1 min.

Using a wire-bar a 12 μm wet film was deposited on a PET substrate and dried for 15 min at 130° C. in an oven. The sheet resistance was determined.

TABLE 1
Dilution of inventive dispersion 5A and reference dispersion 2A
with different solvents and sheet resistance of the respective films.

| | polythiophene | | |
|---|---|---|---|
| Example | dispersion | added solvent | SR (Ohm/sq) |
| 6A (inventive) | 5 g dispersion 5A | 5 g DMSO | 1.5 × 10⁵ |
| 6B (inventive) | 5 g dispersion 5A | 5 g n-butanol | 2.2 × 10⁴ |
| 6C (reference) | 5 g dispersion 2A | 5 g DMSO | 1.8 × 10¹¹ |
| 6D (reference) | 5 g dispersion 2A | 5 g n-butanol | 6.9 × 10¹⁰ |

Table 1 shows that the inventive dispersion 5A gives low sheet resistance values of less 1.5×10⁵ Ohm/sq with various solvents whilst dispersion 2A gives values of up to 10¹¹ Ohm/sq.

### Example 7

A 2.5% solution of poly(isobutyl methacrylate) in an anisole/butyl acetate mixture (50%/50% w/w) was prepared. This solution was mixed in different ratios with dispersion 2B. Since both solutions have the same solids content, the ratio of the solution/dispersion corresponds to the ratio of solids in the resulting film.

Additionally, a 2.4% solution of poly(isobutyl methacrylate) in an anisole/butyl acetate mixture (50%/50% w/w) was prepared. This solution was mixed in different ratios with dispersion 3B. Since both solutions have the same solids content, the ratio of the solution/dispersion corresponds to the ratio of solids in the resulting film.

Using a wire-bar 12 μm wet films of all eight mixtures were deposited on PET substrates and dried for 15 min at 130° C. in an oven.

TABLE 2
Sheet resistance and haze of polythiophene/poly(isobutyl
methacrylate) coatings on PET films

| | ratio of polythio- | | | |
|---|---|---|---|---|
| | phene complex | solids | | |
| | and poly(isobutyl | content | sheet | |
| | methacrylate) in | of mixture | resistance | |
| dispersion | dried film (w:w) | [%] | (Ohm/sq) | haze (%) |
| 2B (reference) | 1:9 | 2.5 | 6.3 × 10⁷ | 1.2 |
| 2B (reference) | 1:4 | 2.5 | 5.0 × 10⁶ | 6.7 |
| 2B (reference) | 1:2 | 2.5 | 6.6 × 10⁵ | 13.3 |
| 2B (reference) | 1:1 | 2.5 | 1.3 × 10⁵ | 17.5 |
| 3B (inventive) | 1:9 | 2.4 | 1.6 × 10⁶ | 0.42 |
| 3B (inventive) | 1:4 | 2.4 | 1.7 × 10⁵ | 0.49 |
| 3B (inventive) | 1:2 | 2.4 | 5.5 × 10⁴ | 0.55 |
| 3B (inventive) | 1:1 | 2.4 | 2.6 × 10⁴ | 0.8 |

Table 2 shows that the inventive dispersion 3B results in lower sheet resistance and lower haze when blended with poly(isobutyl methacrylate) compared to reference dispersion 2B.

### Example 8

### According to the Present Invention

In Example 8 the following complex is prepared:

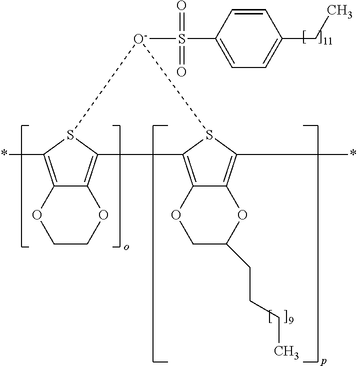

Dispersion 8A:

A 100 ml three-necked round-bottom flask equipped with mechanical stirrer, condenser and nitrogen inlet was charged with 29.7 g anisole (Aldrich), 2.7 g of dibenzoyl peroxide (11.1 mmol; Aldrich) and 3.0 g dodecylbenzene sulfonic acid (9.3 mmol; DBSA; Aldrich). After heating to 60° C. 0.42 g of 3,4-ethylenedioxythiophene (3 mmol; Clevios M V2; Heraeus Deutschland GmbH & Co KG, Germany) and 1.38 g of 2-butyl-2,3-dihydrothieno[3,4b][1,4]dioxine (7 mmol; ButylEDOT; CAS 552857-06-4, Synmax Biochemical, Taiwan) are added. The dispersion was stirred for another 3 h at 60° C. under nitrogen. Then 35 g of anisole were added. After cooling to room temperature, the dispersion was let to stand overnight. This dispersion is called dispersion 8A.

Dispersion 8B:

5 g of dispersion 6A, 3 g anisole and 2 g butanol were mixed in a 20 ml glass bottle and subjected to 1 min of ultrasound treatment (Hielscher UP 200 S, cycle 1, amplitude 100%). This material is called dispersion 8B.

Using a wire-bar a 12 μm wet film was deposited on a PET substrate and dried for 15 min at 130° C. in an oven. The film was characterized by the following properties:

Sheet resistance (12 μm on PET) 17,400 Ohm/sq

Haze (12 μm on PET) 0.7

### Example 9

### According to the Present Invention

The synthesis of example 8 was repeated using 0.846 g of 3,4-ethylenedioxythiophene (6 mmol) and 0.79 g of 2-butyl-2,3-dihydrothieno[3,4b][1,4]dioxine (4 mmol). All other parameters remained unchanged. The final material obtained after ultrasound treatment is called dispersion 9B.

### Example 10

### According to the Present Invention

The synthesis of example 8 was repeated using 0.705 g of 3,4-ethylenedioxythiophene (5 mmol) and 0.98 g of 2-butyl-2,3-dihydrothieno[3,4b][1,4]dioxine (5 mmol). All other parameters remained unchanged. The final material obtained after ultrasound treatment is called dispersion 10B.

### Example 11

### According to the Present Invention

The synthesis of example 8 was repeated using 0.56 g of 3,4-ethylenedioxythiophene (4 mmol) and 1.18 g of 2-butyl-2,3-dihydrothieno[3,4b][1,4]dioxine (6 mmol). All other parameters remained unchanged. The final material obtained after ultrasound treatment is called dispersion 11B.

### Example 12

### According to the Present Invention

The synthesis of example 8 was repeated using 2-butyl-2,3-dihydrothieno-[3,4b][1,4]dioxine in an amount of 10 mmol. No 3,4-ethylenedioxythiophene was used. All other parameters remained unchanged. The dispersion that is obtained after cooling to room temperature and standing overnight is called dispersion 12A. The final material obtained after ultrasound treatment is called dispersion 12B.

Using a wire-bar 12 μm wet films were deposited from dispersions 9B to 12B pursuant to Example 8 on a PET substrate and dried for 15 min at 130° C. in an oven. The films were characterized by their sheet resistance and haze.

Ion-content of 12 B was measured by inductively coupled plasma optical emission spectrometry:

| | |
|---|---|
| Na content: | 1.4 ppm |
| Ca content: | 2.8 ppm |
| Mg content: | 0.02 ppm |

K, Fe, Cu, Pb, Al, Cr, Co, Mn, Ni, V, Zn and Cd were below the detection limit of 0.025 ppm.

Table 3 summarizes the results of Dispersions 2B and 8B to 12B with respect to sheet resistance and haze.

TABLE 3
Sheet resistance and Haze of films prepared with dispersions
2B and 8B-12B

| | | amount | | | | |
|---|---|---|---|---|---|---|
| | side chain | of EDT- | amount | | sheet re- | |
| disper- | in EDT- | derivative | of EDT | count- | sistance | haze |
| sion | derivative | [mmol] | [mmol] | erion | (Ohm/sq) | (%) |
| 2B | none | — | 35 | Nexar ® | 17,000 | 0.6 |
| | | | | MD | | |
| 9B | n-butyl | 4 | 6 | DBSA | 4,100 | 6.1 |
| 10B | n-butyl | 5 | 5 | DBSA | 7,300 | 3.1 |
| 11B | n-butyl | 6 | 4 | DBSA | 14,400 | 0.7 |
| 8B | n-butyl | 7 | 3 | DBSA | 17,400 | 0.7 |
| 12B | n-butyl | 10 | 0 | DBSA | 80,000 | 0.5 |

### Example 13

### According to the Present Invention

A solution of poly(isobutylmethacrylate) (PIBM) was prepared. For that purpose, 13.6 g poly(isobutyl methacrylate) were dissolved in a mixture of 220 g anisole, 132 g butyl acetate and 88 g butanol.
Series 1 of blends:
A series of blends of PIBM solution with dispersions 2B and 8B-12B were prepared. 9 g of the PIBM solution were mixed with 0.34 g of dispersion 12B and 0.55 g anisole, 0.33 g butyl acetate and 0.22 g of butanol. The mass ratio of the non-conductive PIBM and the polythiophene/DBSA complex is 36:1. In the same way 0.34 g of dispersions 2B and 8B to 11B were blended with 9 g of PIBM solution and additional solvents.
Series 2 of blends:
A second series of blends was prepared. 4 g of the PIBM solution were mixed with 0.29 g of dispersion 12B and 0.35 g anisole, 0.21 g butyl acetate and 0.14 g butanol. The mass ratio of the non-conductive PIBM and the polythiophene/DBSA complex is 19:1. In the same way 0.29 g of dispersions 2B and 8B to 11B were blende with 4 g of PIBM solution and additional solvents.

Using a wire-bar a 12 um wet film of the dispersions in series 1 and 2 was deposited on PET substrates and dried for 15 min at 130° C. in an oven. The films were characterized by their sheet resistance. Table 4 summarizes the results.

TABLE 4
Sheet resistance of films prepared with dispersions
2B and 8B-12B into which PIBM has been added

| | | | | | sheet re- | sheet re- |
|---|---|---|---|---|---|---|
| | | | | | sistance | sistance |
| | | | | | in blend | in blend |
| | | amount | | | with | with |
| | side chain | of EDT- | amount | | PIBM | PIBM |
| disper- | in EDT- | derivative | of EDT | counter | 1:19 | 1:36 |
| sion | derivative | [mmol] | [mmol] | ion | (Ω/sq) | (Ω/sq) |
| 2B¹⁾ | none | — | 35 | Nexar ® | 2 × 10¹¹ | 2 × 10¹¹ |
| | | | | MD | | |
| 9B | n-butyl | 4 | 6 | DBSA | 4 × 10¹⁰ | 2 × 10¹¹ |
| 10B | n-butyl | 5 | 5 | DBSA | 3 × 10⁹ | 1 × 10¹⁰ |
| 11B | n-butyl | 6 | 4 | DBSA | 4 × 10⁷ | 1 × 10¹⁰ |
| 8B | n-butyl | 7 | 3 | DBSA | 1 × 10⁷ | 2 × 10⁷ |
| 12B | n-butyl | 10 | 0 | DBSA | 1 × 10⁷ | 1 × 10⁷ |

(¹⁾not according to the present invention)

Table 4 clearly shows the advantage of polythiophenes comprising alkyl-EDOT.

### Example 14

### According to the Present Invention

The dispersion obtained in Example 12A was diluted with a range of solvents. Table 5 shows solvent mixtures.

### Example 14B

5 g of Dispersion 12 B were mixed with 3 g anisole and 2 g n-butanol. The resulting solvent mixture contained 80% anisole (w/w) and 20% n-butanol (w/w). Using a wire-bar a 12 μm wet films of dispersions was deposited on PET substrates and dried for 15 min at 130° C. in an oven. The solids content was 2.2%. The sheet resistance was 8×10⁴ Ohm/sq

### Example 14C

5 g dispersion were mixed with 10 g anisole and 5 g n-butanol. The resulting solvent mixture contained 75% anisole and 25% n-butanol. The solids content was 1.1%. Using a wire-bar a 12 μm wet films of dispersions was deposited on PET substrates and dried for 15 min at 130° C. in an oven. The sheet resistance was 16×10⁴ Ohm/sq.

Examples 14D, 14 E, 14F and 14 G are prepared accordingly.

Table 5 shows the compositions and resulting sheet resistances:

TABLE 5
Blends of dispersion 12A with various solvents

| dis- | concen- | | | | | | | | sheet re- |
|---|---|---|---|---|---|---|---|---|---|
| per- | tration | | butyl | | ethyl | n- | iso- | | sistance |
| sion | [wt.-%] | anisole | acetate | toluene | acetate | butanol | propanol | PGME | (S)/sq) |
| 14B | 2.2 | 80 | | | | 20 | | | 8 × 10⁴ |
| 14C | 1.1 | 75 | | | | 25 | | | 16 × 10⁴ |
| 14D | 1.1 | 50 | 50 | | | | | | 16 × 10⁴ |
| 14E | 1.1 | 25 | 25 | 50 | | | | | 11 × 10⁴ |
| 14F | 2.2 | 50 | | | 30 | 20 | | | 8 × 10⁴ |
| 14G | 1.1 | 40 | | | | 10 | 25 | 25 | 25 × 10⁴ |

In all six cases uniform dispersions were obtained that do not form particles or precipitates. Table 5 also clearly shows the advantage of polythiophenes comprising alkyl-EDOT.

### Example 15

### According to the Present Invention

A 100 ml three-necked round-bottom flask equipped with mechanical stirrer, condenser and nitrogen inlet was charged with 29.7 g anisole (Aldrich), 2.7 g of dibenzoyl peroxide (11.1 mmol; Aldrich) and 3.0 g dodecylbenzene sulfonic acid (9.3 mmol; DBSA; Aldrich). After heating to 60° C. 0.56 g of 2-decyl-2,3-dihydrothieno[3,4b][1,4]dioxine (2 mmol; DecylEDOT; CAS 126213-55-6) and 1.58 g of 2-butyl-2,3-dihydrothieno[3,4b][1,4]dioxine (8 mmol; ButylEDOT; CAS 552857-06-4) are added. The dispersion was stirred for another 3 h at 60° C. under nitrogen. Then 35 g of anisole were added. After cooling to room temperature, the dispersion was let to stand overnight. This dispersion is called dispersion 15A.

Dispersion 15B:

5 g of dispersion 15A, 3 g anisole and 2 g butanol were mixed in a 20 ml glass bottle and subjected to 1 min of ultrasound treatment (Hielscher UP 200 S, cycle 1, amplitude 100%). This material is called dispersion 15B.

Solids content: 2.4%

Using a wire-bar a 12 μm wet film was deposited on a PET substrate and dried for 15 min at 130° C. in an oven. The film was characterized by the following properties:

Sheet resistance (12 μm on PET) 64,000 Ohm/sq

Haze (12 μm on PET) 0.8

### Example 16

### According to the Present Invention

Poly(n-butylacrylate) is an example of a polyacrylate with a low glass-transition temperature (Tg=−54° C.). Poly(n-butylacrylate) in toluene (CAS 9003-49-0; 25 wt % in toluene, M_{w} 99000 g/mol; Sigma Aldrich product 181404) was blended with Dispersion 15B. Table 6 shows the blending ratio of three mixtures.

Using a wire-bar a 12 μm wet film was deposited on a PET substrate for each mixture and dried for 15 min at 130° C. in an oven. The sheet resistance was measured.

TABLE 6
Blends of Dispersion 15 B with poly(n-butylacrylate)
and their sheet resistance

| | mass of | | | ratio of poly | |
|---|---|---|---|---|---|
| | Polybutyl- | | | butylacrylate: | |
| | acrylate | mass of | | polythiophene | |
| | solution | Dispersion | mass of | complex | Sheet |
| | (25%) in | 15 B | Added | in dried | resistance |
| Sample | toluene | (2.4%) | Toluene | film | [Ohm/sq] |
| 16A | 5 g | 5.2 g | 0 g | 90:10 | 5.5 × 10⁷ |
| 16B | 5 g | 4.0 g | 1.2 g | 92.5:7.5 | 8.2 × 10⁸ |
| 16C | 5 g | 2.0 g | 3.2 g | 97.5:3.7 | 6.6 × 10⁹ |

### Example 17

### Reference Example for the Synthesis of 3-(2-ethylhexoxymethyl)-2,3-dihydrothieno[3,4-b][1,4]dioxine

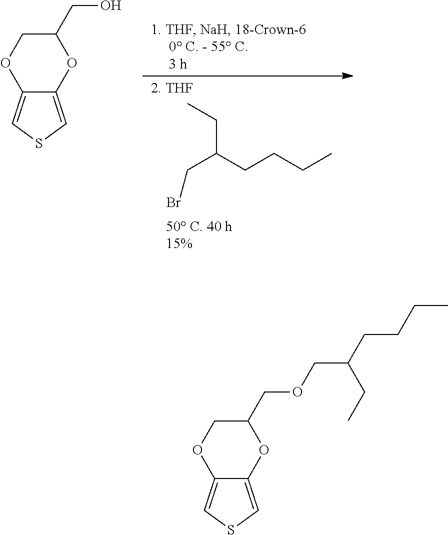

The synthesis is conducted under dry and inert conditions.

THF (60 mL) and 18-Crown-6 (0.200 g, 0.8 mmol) are added to the reaction vessel. NaH (1.512 g, 37.8 mmol) as 60% suspension in oil is added under stirring, the mixture is stirred at room temperature. At 0° C. a EDOT-MeOH (5.00 g, 29.0 mmol) solution in 20 mL THF is added to the NaH solution. After addition of the solution the reaction mixture is stirred for 2.5 h at room temperature, subsequently 0.5 h at 55° C. Reaction mixture is cooled to 0° C. and a 2-ethylhexyl bromide (7.300 g, 37.8 mmol) solution in 20 mL THF is added. The reaction mixture is stirred for 1 h at room temperature and 40 h at 50° C. The reaction mixture is cooled to room temperature and quenched with a mixture of isopropanol/water 70:30 (v/v). The crude product was purified by column chromatography.

The reaction product (3-(2-ethylhexoxymethyl)-2,3-dihydrothieno[3,4-b][1,4]dioxine) is obtained as a yellow oil in a yield of 15%.

### Example 18

### Reference Example for the Synthesis of 3-(1-phenylethoxymethyl)-2,3-dihydrothieno[3,4-b][1,4]dioxine

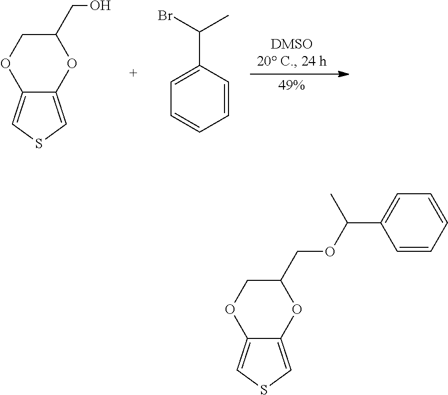

The synthesis is conducted under dry and inert conditions.

DMSO (50 mL), KOH (3.254 g, 58 mmol), 1-bromoethyl)benzene (6.700 g, 37.8 mmol) , and EDOT-MeOH (5.00 g, 29.0 mmol) are added to the reaction vessel. The resulting reaction mixture is stirred at 20° C. for 24 h. After the reaction is completed, the reaction mixture is poured into deionized water (1000 mL) and stirred for 1 h. The volume of the resulting mixture is halved by vacuum distillation. The mixture is extracted three times with ethyl acetate (150 ml), the combined organic phases are washed with brine (150 ml), dried over MgSO₄ and the solvent is removed in vacuo. The crude product is purified by column chromatography.

The reaction product 3-(1-phenylethoxymethyl)-2,3-dihydrothieno[3,4-b][1,4]dioxine) is obtained as a yellow oil in a yield of 49%.

### Example 19

A 250 mL three-necked round-bottom flask equipped with mechanical stirrer was charged with 65 g anisole (Aldrich), 2.699 g of dibenzoyl peroxide (11.1 mmol; Aldrich), and 2.981 g 4-dodecylbenzenesulfonic acid (9.3 mmol, Aldrich). After heating to 60° C. 1.185 g of 3-butyl-2,3-dihydrothieno[3,4-b][1,4]dioxine (6 mmol; ButylEDOT; CAS 552857-06-4, Synmax Biochemical, Taiwan) and 1.134 g product obtained from the reaction in Example 17 (4 mmol) dissolved in 20 g of anisole were added over 40 min. The dispersion was stirred for another 3 h at 60° C. and then cooled to room temperature.

50 g of the dispersion, 30 g anisole, and 20 g of n-butanol are added to a 100 mL flask and mixed via gentle stirring of the resulting dispersion.

This is called dispersion 19.

Analysis of dispersion 19:

Solids content: 2.4% (gravimetric)

Sheet resistance (12 μm on PET): 210000 Ohm/sq

The ion-content of dispersion 19 was measured by inductively coupled plasma optical emission spectrometry:

Na 0.324 ppm

Fe 0.043 ppm

Cu 0.000 ppm

Pb 0.000 ppm

B 0.010 ppm

Mo 0.370 ppm

Al 0.000 ppm

Cr 0.028 ppm

Co 0.000 ppm

Mn 0.000 ppm

Ni 0.000 ppm

V 0.000 ppm

Zn 0.514 ppm

Ca 0.172 ppm

K 0.000 ppm

Mg 0.077 ppm

Cd 0.012 ppm

### Example 20

A 250 mL three-necked round-bottom flask equipped with mechanical stirrer was charged with 65 g anisole (Aldrich), 2.699 g of dibenzoyl peroxide (11.1 mmol; Aldrich), and 2.981 g 4-dodecylbenzenesulfonic acid (9.3 mmol, Aldrich). After heating to 60° C. 1.185 g of 3-butyl-2,3-dihydrothieno[3,4-b][1,4]dioxine (10 mmol; ButylEDOT; CAS 552857-06-4, Synmax Biochemical, Taiwan) dissolved in 20 g of anisole were added over 40 min. The dispersion was stirred for another 3 h at 60° C. and then cooled to room temperature.

50 g of the dispersion, 30 g anisole, and 20 g of n-butanol are added to a 100 mL flask and mixed via gentle stirring of the resulting dispersion.

This is called dispersion 20.

Analysis of dispersion 20:

Solids content: 2.2% (gravimetric)

Sheet resistance (12 μm on PET): 70000 Ohm/sq

### Example 21

Dispersion 19 and dispersion 20 were tested with respect to their solvent compatibility. 1 g of the named dispersion is mixed by gentle stirring and shaking with 9 g of the additional solvent as shown in Table 7.

Using a wire-bar a 12 μm wet film was deposited on a PET substrate and dried for 15 min at 130° C. in an oven. The surface resistivity was determined.

A blank PET substrate yields the following baseline values upon measurement:

Surface resistivity: 1.8×10¹¹ Ohm/sq

Transmission: 91%

TABLE 7
Dilution of dispersion 19 and dispersion 20 with various solvents.

| | | | | surface | trans- |
|---|---|---|---|---|---|
| | | | | resistivity | mission |
| Example | dispersion | solvent | solubility | [Ohm/sq] | [%] |
| 21A | 19 | 1-Methoxy- | + | 1.1 × 10⁷ | 89 |
| | | 2-propanol | | | |
| 21B | 19 | isopropanol | + | 1.6 × 10⁷ | 89 |
| 21C | 19 | toluene | + | 1.2 × 10⁷ | 89 |
| 21D | 19 | butyl acetate | + | 1.8 × 10⁷ | 89 |
| 21E | 19 | butyl benzoate | + | 1.0 × 10⁷ | 89 |
| 21F | 19 | 1-methoxy-2- | + | 1.2 × 10⁷ | 89 |
| | | propylacetat | | | |
| 21G | 19 | ethyl acetate | + | 1.4 × 10⁷ | 89 |
| 21H | 19 | anisole | + | 6.7 × 10⁶ | 89 |
| 21I | 20 | 1-Methoxy- | + | 1.7 × 10⁶ | 89 |
| | | 2-propanol | | | |
| 21J | 20 | ethanol | + | 3.9 × 10⁷ | 90 |
| 21K | 20 | butyl acetate | + | 1.0 × 10⁶ | 89 |
| 21L | 20 | anisole | + | 7.8 × 10⁵ | 89 |

Table 7 shows that the dispersion from the inventive example 19 and 20 are demonstrating a good surface resistivity and forms stable dispersions in a variety of common organic solvents.

### Example 22

A 250 mL three-necked round-bottom flask equipped with mechanical stirrer was charged with 65 g anisole (Aldrich), 2.699 g of dibenzoyl peroxide (11.1 mmol; Aldrich), and 2.981 g 4-dodecylbenzenesulfonic acid (9.3 mmol, Aldrich). After heating to 60° C. 1.565 g of 3-butyl-2,3-dihydrothieno[3,4-b][1,4]dioxine (8 mmol; ButylEDOT; CAS 552857-06-4, Synmax Biochemical, Taiwan) and 0.565 g of 3-decyl-2,3-dihydrothieno[3,4-b][1,4]dioxine (2 mmol; CAS: 210476-55-4) dissolved in 20 g of anisole were added over 40 min. The dispersion was stirred for another 3 h at 60° C. and then cooled to room temperature.

50 g of the dispersion, 30 g anisole, and 20 g of n-butanol are added to a 100 mL flask and mixed via gentle stirring of the resulting dispersion.

This is called dispersion 22.

Analysis of dispersion 22:

Solids content: 2.3% (gravimetric)

Sheet resistance (12 μm on PET): 63000 Ohm/sq

### Example 23

Dispersion 19 and dispersion 22 were tested with respect to their compatibility with acrylic resins. Table 8 shows the amounts of used dispersions, solvents, and dipentaerythritol penta-/hexa-acrylate (CAS 60506-81-2, Sigma Aldrich).

Using a wire-bar a 12 μm wet film was deposited on a PET substrate and dried for 15 min at 130° C. in an oven. The surface resistivity was determined.

TABLE 8
Surface resistivity of dispersion 19 and dispersion 22 in an acrylic resin.

| | | | dipentaerythritol | surface |
|---|---|---|---|---|
| | | | penta-/hexa-acry- | resistivity |
| Example | dispersion | solvent | late [g] | [Ohm/sq] |
| 23A | 0.6 g | 8.4 g 1-methoxy-2- | 1 | 6.1 × 10¹⁰ |
| | dispersion 19 | propanol | | |
| 23B | 1.5 g | 7.5 g 1-methoxy-2- | 1 | 2.5 × 10⁹ |
| | dispersion 19 | propanol | | |
| 23C | 2.4 g | 6.6 g 1-methoxy-2- | 1 | 6.1 × 10⁷ |
| | dispersion 19 | propanol | | |
| 23D | 0.6 g | 8.4 g ethyl acetate | 1 | 1.1 × 10¹¹ |
| | dispersion 19 | | | |
| 23E | 1.5 g | 7.5 g ethyl acetate | 1 | 5.5 × 10⁸ |
| | dispersion 19 | | | |
| 23F | 2.4 g | 6.6 g ethyl acetate | 1 | 7.7 × 10⁸ |
| | dispersion 19 | | | |
| 23G | 2.4 g | 6.6 g ethyl acetate | 1 | 7.0 × 10⁷ |
| | dispersion 22 | | | |

Table 8 shows the compatibility of dispersions 19 and 22 with acrylic resins as demonstrated in the achieved surface resistivity values.

### Example 24

Dispersion 19 and dispersion 2B were compared with respect to their compatibility with silicon release resins. Table shows the amounts of used dispersions, solvents, and KS 847-H (CAS: 63148-53-8; Shin-Etsu Silicone). As a solvent, a mixture of toluene, alkanes and ketones is used.

Using a wire-bar a 12 μm wet film was deposited on a PET substrate and dried for 15 min at 130° C. in an oven. The surface resistivity was determined.

TABLE 9
Surface resistivity of dispersion 19 and dispersion 24 in a
silicone release resin.

| | | | | surface |
|---|---|---|---|---|
| | | solvent | KS 847-H | resistivity |
| Example | dispersion | [g] | [g ] | [Ohm/sq] |
| 24A (inventive) | 0.5 g dispersion 19 | 10 | 1.3 | 1.5 × 10¹¹ |
| 24B (inventive) | 1 g dispersion 19 | 10 | 1.3 | 1.3 × 10⁹ |
| 24C (inventive) | 2 g dispersion 19 | 10 | 1.3 | 2.3 × 10⁷ |
| 24E (comparative) | 0.5 g dispersion 2B | 10 | 1.3 | 2.3 × 10¹¹ |
| 24F (comparative) | 1 g dispersion 2B | 10 | 1.3 | 2.3 × 10¹¹ |
| 24G (comparative) | 2 g dispersion 2B | 10 | 1.3 | 2.3 × 10¹¹ |

Table 9 shows the superior compatibility of dispersion 19 with silicone release resins as demonstrated in the achieved surface resistivity values.

### Example 25

Dispersion 19 and dispersion 22 were tested with respect to their compatibility with polyacrylic resins. Table 10 shows the amounts of used dispersions, solvents, and polybutylacrylate (CAS 9003-49-0, Sigma Aldrich).

Using a wire-bar a 12 μm wet film was deposited on a PET substrate and dried for 15 min at 130° C. in an oven. The surface resistivity was determined.

TABLE 10
Surface resistivity of dispersion 19 and dispersion
22 in a polyacrylic binder.

| | | | | surface |
|---|---|---|---|---|
| | | | polybutyl | resistivity |
| Example | dispersion | toluene [g] | acrylate [g] | [Ohm/sq] |
| 25A | 0.455 g dispersion 19 | 5.545 | 4 | 4.1 × 10¹⁰ |
| 25B | 1.136 g dispersion 19 | 4.864 | 4 | 5.3 × 10⁹ |
| 25C | 2.273 g dispersion 19 | 3.727 | 4 | 1.7 × 10⁹ |
| 25D | 2.273 g dispersion 22 | 3.727 | 4 | 1.7 × 10⁹ |

Table 10 shows the compatibility of the dispersion 19 and 22 with poly(meth)acrylate binders as demonstrated in the achieved surface resistivity.

### Example 26

A 250 mL three-necked round-bottom flask equipped with mechanical stirrer was charged with 65 g anisole (Aldrich), 2.699 g of dibenzoyl peroxide (11.1 mmol; Aldrich), and 2.981 g 4-dodecylbenzenesulfonic acid (9.3 mmol, Aldrich). After heating to 60° C. 1.584 g of 3-butyl-2,3-dihydrothieno[3,4-b][1,4]dioxine (8 mmol; ButylEDOT; CAS 552857-06-4, Synmax Biochemical, Taiwan) and 0.553 g product obtained from the reaction in Example 18 (2 mmol) dissolved in 20 g of anisole were added over 40 min. The dispersion was stirred for another 3 h at 60° C. and then cooled to room temperature.

5 g of the dispersion, 3 g anisole, and 2 g of n-butanol are mixed via gentle stirring and subjected to 1 min of ultrasound treatment (Hielscher UP 200 S, cycle 1, amplitude 100%) to yield the resulting dispersion.

This is called dispersion 26.

Analysis of dispersion 26:

Solids content: 2.4% (gravimetric)

Sheet resistance (12 μm on PET): 19000 Ohm/sq

### LIST OF REFERENCE NUMERALS

100 layer body

101 substrate

102 electrically conductive layer

1. A composition comprising
i) at least one polythiophene comprising monomer units of structure (IA) or (Ib) 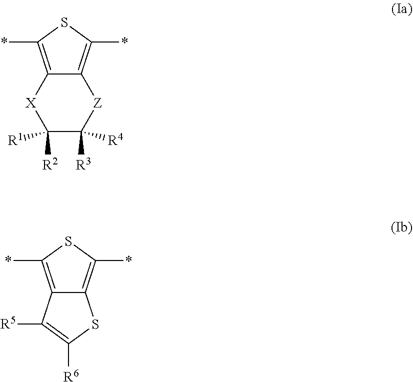
in which
* indicates the bond to the neighboring monomer units,
X,Z represent O or S,
R¹-R⁶ independently from each other represent a hydrogen atom or an organic residue R,
with the proviso that at least one of residues R¹ to R⁴ and one of residues R⁵ and R⁶ represents an organic residue R;
ii) at least one organic compound carrying one or two inorganic acid group(s) selected from the group consisting of one or two sulfonic acid group(s), one or two sulfuric acid group(s), one or two phosphonic acid group(s), one or two phosphoric acid group(s), and a salt of said organic compound, wherein the molecular weight of the organic compound or the salt thereof is less than 1,000 g/mol; and
iii) at least one organic solvent.

2. The composition according to claim 1, wherein the composition is a dispersion, wherein the polythiophene i) and the organic compound ii) form a complex that is homogeneously dispersed in the organic solvent iii).

3. The composition according to claim 1, wherein the organic residue R does not carry anionic groups.

4. The composition according to claim 1, wherein the polythiophene is a homopolymer or copolymer comprising monomer units of structure (Ia) in which X and Z represent O, and wherein three of the residues selected from the group consisting of R¹, R², R³ and R⁴ represent a hydrogen atom and the remaining residue represents an ether group having the structural formula (IIa)
—(CR⁷R⁸)ₙ—O—R⁹ (IIa)
wherein
R⁷ is H, a C₁-C₁₀-alkyl group or a C₁-C₁₀-alkoxy group, preferably H;
R⁸ is H, a C₁-C₁₀-alkyl group or a C₁-C₁₀-alkoxy group, preferably H;
n is an integer in the range from 0 to 10; and
R⁹ is a C₁-C₃₀ alkyl group, an alkoxy group, an aryl group, an ether group or an ester group.

5. The composition according to claim 1, wherein the polythiophene is a homopolymer or copolymer comprising monomer units of structure (Ia) in which X and Z represent O, and wherein three of the residues selected from the group consisting of R¹, R², R³ and R⁴ represent a hydrogen atom and the remaining residue represents an alkyl group having formula (IIb)
—CₙH₂ₙ₊₁ (IIb)
wherein n is an integer in the range from 1 to 20.

6. The composition according to claim 1, wherein the polythiophene is a homopolymer or copolymer comprising monomer units of structure (Ia) in which X and Z represent O, and wherein three of the residues selected from the group consisting of R¹, R², R³ and R⁴ represent a hydrogen atom and the remaining residue represents a branched alkyl group or a branched ether group.

7. The composition according to claim 6, wherein the remaining residue represents a branched ether group having the structural formula (IIc)
—(CR¹⁰ R¹¹)ₙ—O—R¹² (IIc)
wherein
R¹⁰ is H, a C₁-C₁₀-alkyl group or a C₁-C₁₀-alkoxy group;
R¹¹ is H, a C₁-C₁₀-alkyl group or a C₁-C₁₀-alkoxy group;
n is an integer in the range from 0 to 10; and
R¹² is a branched alkyl group or a branched arylalkyl group, wherein neither the branched alkyl group nor the branched arylalkyl group comprise an unsaturated C═C-bond in the alkyl chain.

8. The composition according to claim 7, wherein R¹² is an organic residue having formula (IId)
—(CHR¹³)ₘ—R¹⁴ (IId)
wherein
m is 1, 2 or 3,
R¹³ is H or a C₁-C₁₂ alkyl group, with the provisio that in only one of the structural units —CHR¹³— residue R¹³ is a C₁-C₁₂ alkyl group;
R¹⁴ is a C₁-C₁₀-alkyl group or a aryl group.

9. The composition according to claim 1, wherein the composition further comprises
iv) at least one non-conductive oligomeric or polymeric binder, preferably a poly(meth)acrylate and/or a polysilicone.

10. The composition according to claim 1, wherein the organic compound ii) is an anionic surfactant.

11. The composition according to claim 1, wherein the at least one organic solvent iii) is selected from the group consisting of toluene, xylene, anisole, methyl benzoate, ethyl benzoate, propyl benzoate, butyl benzoate, methyl acetate, ethyl acetate, propyl acetate, butyl acetate, octyl acetate, methyl propionate, ethyl propionate, propyl propionate, butyl propionate, 1-methoxy-2-propylacetat, 1-methoxy-2-propanol, butanol, 2-propanol, ethanol and mixtures thereof or mixtures of one or two of these aprotic solvents with one or two further solvents.

12. The composition according to claim 1, wherein the composition has an iron content of less than 30 ppm, based on the total weight of the composition.

13. A process for preparing a composition, the process comprising the steps of
I) providing a reaction mixture comprising
i) thiophene monomers of structure (VIa) or (VIb) 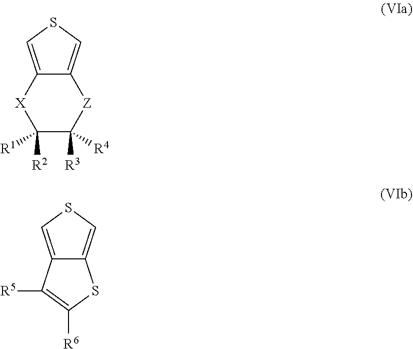
in which
X,Z represent O or S,
R¹-R⁶ independently from each other represent a hydrogen atom or an organic residue R,
with the proviso that at least one of residues R¹ to R⁴ and one of residues R⁵ and R⁶ represents an organic residue R;
ii) at least one organic compound carrying one or two inorganic acid group(s), preferably one or two sulfonic acid group(s), one or two sulfuric acid group(s), one or two phosphonic acid group(s) or one or two phosphoric acid group(s), or a salt of said organic compound, wherein the molecular weight of the organic compound or the salt thereof is less than 1,000 g/mol;
iii) at least one organic solvent; and
iv) at least one oxidizing agent, preferably at least one organic peroxide;
II) oxidatively polymerizing the thiophene monomers for the formation a polythiophene.

14. The process according to claim 13, wherein the reaction mixtures provided in process step I) comprises thiophene monomers of structure (VIa) in which X and Z represent O, and wherein three of the residues selected from the group consisting of R¹, R², R³ and R⁴ represent a hydrogen atom and the remaining residue represents an ether group having the structural formula (IIa)
—(CR⁷R⁸)ₙ—O—R⁹ (IIa)
wherein
R⁷ is H, a C₁-C₁₀-alkyl group or a C₁-C₁₀-alkoxy group;
R⁸ is H, a C₁-C₁₀-alkyl group or a C₁-C₁₀-alkoxy group;
n is an integer in the range from 0 to 10; and
R⁹ is an alkyl group, an alkoxy group, an aryl group, an ether group or an ester group, preferably a C₁-C₃₀ alkyl group.

15. The process according to claim 13, wherein the reaction mixtures provided in process step I) comprises thiophene monomers of structure (VIa) in which X and Z represent O, and wherein three of the residues selected from the group consisting of R¹, R², R³ and R⁴ represent a hydrogen atom and the remaining residue represents an alkyl group having formula (IIb)
—CₙH₂ₙ₊₁ (IIb)
wherein n is an integer in the range from 1 to 20.

16. The process according to claim 13, wherein the reaction mixtures provided in process step I) comprises thiophene monomers of structure (VIa) in which X and Z represent O, and wherein three of the residues selected from the group consisting of R¹, R², R³ and R⁴ represent a hydrogen atom and the remaining residue represents a branched alkyl group or a branched ether group.

17. The process according to claim 16, wherein the remaining residue represents a branched ether group having the structural formula (IIc)
—(CR¹⁰R¹¹)ₙ—OR¹² (IIc)
wherein
R¹⁰ is H, a C₁-C₁₀-alkyl group or a C₁-C₁₀-alkoxy group;
R¹¹ is H, a C₁-C₁₀-alkyl group or a C₁-C₁₀-alkoxy group;
n is an integer in the range from 0 to 10; and
R¹² is a branched alkyl group or a branched arylalkyl group, wherein neither the branched alkyl group nor the branched arylalkyl group comprise an unsaturated C═C-bond in the alkyl chain.

18. The process according to claim 17, wherein R¹² is an organic residue having formula (IId)
—(CHR¹³)ₘ—R¹⁴ (IId)
wherein
m is 1, 2 or 3,
R¹³ is H or a C₁-C₁₂ alkyl group, with the provisio that in only one of the structural units —CHR¹³— residue R¹³ is a C₁-C₁₂ alkyl group;
R¹⁴ is a C₁-C₁₀-alkyl group or a aryl group.

19. A layer structure comprising a substrate and an electrically conductive layer applied onto the substrate, wherein the electrically conductive layer comprises a polythiophene i) as defined in in claim 1 and at least one organic compound ii) carrying one or two inorganic acid group(s), preferably one or two sulfonic acid group(s), one or two sulfuric acid group(s), one or two phosphonic acid group(s) or one or two phosphoric acid group(s), or a salt of said organic compound, as defined in claim 1.

20. A process for the preparation of a layer structure, comprising the process steps of
A) provision of a substrate;
B) coating a substrate (with a composition according to claim 1
C) at least partial removal of the organic solvent iii) for the formation of an electrically conductive layer.

21. An electronic component comprising a layer structure according to claim 19.

22. (canceled)
